(19) United States
(12) Patent Application Publication
(10) Pub. No.: US 2026/0076024 A1
(43) Pub. Date: Mar. 12, 2026

(54) CROSSLINKING AGENT, LIGHT-EMITTING DEVICE AND DISPLAY PANEL

(71) Applicant: Yungu (Gu’an) Technology Co., Ltd., Langfang (CN)

(72) Inventors: Zhimin YAN, Langfang (CN); Fengjie JIN, Langfang (CN); Liang SU, Langfang (CN); Fuxing JIAO, Langfang (CN); Wangfeng XI, Langfang (CN)

(73) Assignee: Yungu (Gu’an) Technology Co., Ltd., Langfang (CN)

(21) Appl. No.: 19/388,903

(22) Filed: Nov. 13, 2025

(30) Foreign Application Priority Data
Nov. 29, 2024 (CN) 202411746274.5

(51) Int. Cl. H10K 50/115; H10K 50/15; H10K 50/17; H10K 50/18; H10K 59/122; H10K 85/60

(52) U.S. Cl. CPC H10K 50/115; H10K 50/15; H10K 50/171; H10K 50/181; H10K 59/122; H10K 85/626; H10K 85/633; H10K 85/6572

(57) ABSTRACT

The present application provides a crosslinking agent, a light-emitting device and a display panel, and the preparation methods therefor. The crosslinking agent includes an electroactive group and a crosslinking group, wherein the electroactive group and the crosslinking group are bonded, and the crosslinking group is located on at least a portion of the periphery of the electroactive group. For the crosslinking agent provided according to an embodiment of the present application, the electroactive group is conductive, which facilitates the transport of electrons or holes. Thus, the application of the crosslinking agent to a light-emitting functional layer of a light-emitting device is beneficial for improving the electron/hole transport performance of the light-emitting functional layer and lowering the voltage of the light-emitting device, resulting in reduced power consumption of the light-emitting device.

### CROSS-REFERENCE TO RELATED APPLICATIONS

The present application claims priority to Chinese Patent Application No. 202411746274.5, entitled “CROSSLINKING AGENT, LIGHT-EMITTING DEVICE AND DISPLAY PANEL” and filed on Nov. 29, 2024, the entire contents of which are incorporated herein by reference.

### FIELD

The present application relates to the field of displays, and in particular to a crosslinking agent, a light-emitting device and a display panel, and the preparation methods therefor.

### BACKGROUND

Quantum dot light-emitting diodes (QLED) offer advantages such as a high color gamut, a long potential lifetime, a good viewing angle and low cost, making them a highly promising future display technology. QLED light-emitting devices hold great potential for improving the color gamut of display panels. However, limited by the relevant technologies, current QLED light-emitting devices still cannot adequately meet the requirements.

### SUMMARY

In view of this, an embodiment of the present application provides a crosslinking agent, a light-emitting device and a display panel, and the preparation methods therefor.

One embodiment of the present application provides a crosslinking agent, comprising:
an electroactive group and a crosslinking group, wherein the electroactive group and the crosslinking group are bonded, and the crosslinking group is located on at least a portion of the periphery of the electroactive group.

One embodiment of the present application provides a light-emitting device, comprising:
a first electrode layer, a light-emitting functional layer and a second electrode layer that are stacked, wherein
a raw material of the light-emitting functional layer includes the aforementioned crosslinking agent.

One embodiment of the present application provides a display panel, comprising:
an array substrate;
a pixel defining layer, which is located on a side of the array substrate and comprises a plurality of openings; and
a plurality of the aforementioned light-emitting devices, part of the light-emitting devices being located in the openings.

### BRIEF DESCRIPTION OF THE DRAWINGS

FIG. 1 shows a structural schematic diagram of a crosslinking agent in an embodiment of the present application.

FIG. 2 shows a structural schematic diagram of a light-emitting device in an embodiment of the present application.

FIG. 3 shows a structural schematic diagram of a light-emitting device in another embodiment of the present application.

FIG. 4 shows a structural schematic diagram of a display panel in an embodiment of the present application.

FIG. 5 shows a structural schematic diagram of a display panel in another embodiment of the present application.

FIG. 6 shows a schematic flowchart of a preparation method for a display panel in an embodiment of the present application.

FIG. 7 shows voltage-current density curves of light-emitting devices in Example 1 and Comparative Example 1.

FIG. 8 shows voltage-luminance curves of light-emitting devices in Example 1 and Comparative Example 1.

FIG. 9 shows voltage-luminance curves of light-emitting devices in Example 21 and Comparative Example 2.

FIG. 10 shows voltage-luminance curves of light-emitting devices in Example 26 and Comparative Example 3.

### DETAILED DESCRIPTION OF THE EMBODIMENTS

The embodiments of the present application will be clearly and completely described below with reference to the drawings in the embodiments of the present application. Apparently, the embodiments described are merely part of rather than all of the embodiments of the present application.

In addition, in order to better illustrate the present application, numerous specific details are given in the following detailed description of the embodiments. Embodiments of the present application can also be implemented without certain specific details. In some examples, detailed descriptions of methods and means well-known in the art are omitted to highlight the gist of the present application.

It should be noted that similar reference signs and letters refer to similar items in the following drawings. Therefore, once a specific item is defined in one of the drawings, it may not be further defined and explained in subsequent drawings.

In addition, the terms such as “first” and “second” are used merely to distinguish the descriptions, and should not be construed as indicating or implying the relative importance.

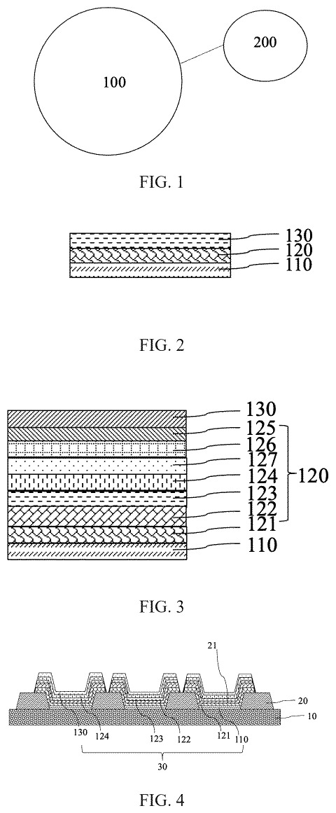

One embodiment of the present application provides a crosslinking agent. With reference to the structural schematic diagram of the crosslinking agent shown in FIG. 1, the crosslinking agent comprises: an electroactive group 100 and a crosslinking group 200, and the electroactive group 100 and the crosslinking group 200 are bonded, and the crosslinking group 200 is located on at least a portion of the periphery of the electroactive group 100.

For the crosslinking agent provided according to an embodiment of the present application, the electroactive group 100 is conductive, which facilitates the transport of electrons or holes. Thus, the application of the crosslinking agent to a light-emitting functional layer of a light-emitting device is beneficial for improving the electron/hole transport performance of the light-emitting functional layer and lowering the voltage of the light-emitting device, resulting in reduced power consumption of the light-emitting device. The crosslinking group 200 is capable of crosslinking with other materials in the light-emitting functional layer, which not only improves the stability of the light-emitting device but also facilitates the patterning of the film layer, thus simplifying the fabrication of the light-emitting devices and increasing the yield of the light-emitting device.

For example, when the crosslinking agent is applied to a light-emitting layer of a light-emitting device, the crosslinking agent and the host material of the light-emitting layer undergo crosslinking upon exposure to light, and the crosslinked network is resistant to development by a developer. At this point, the areas where the light-emitting layer needs to be retained are exposed to light, and the areas where the light-emitting layer does not need to be retained are shielded from exposure, thus resulting in a patterned light-emitting layer after development.

In one embodiment, the electroactive group 100 includes at least one of fluorene, carbazole, aniline, imidazole, pyridine, triazine and pyrimidine. Fluorene, carbazole, and aniline have hole-transport characteristics, and thus the application of the crosslinking agent to a light-emitting device is beneficial for improving the hole transport properties of the light-emitting device. Imidazole, pyridine, triazine and pyrimidine have electron transport characteristics, and thus the application of the crosslinking agent to a light-emitting device is beneficial for improving the electron transport properties of the light-emitting device.

For example, a crosslinking agent comprising fluorene, carbazole, and aniline can be applied either to the hole injection layer and the hole transport layer of a light-emitting device, or to the light-emitting layer of a light-emitting device. For example, when the crosslinking agent is applied to the hole injection layer and the hole transport layer of a light-emitting device, due to the hole transport properties of the crosslinking agent, the hole mobility of the hole injection layer and the hole transport layer will not decrease significantly, thereby lowering the voltage of the light-emitting device. For example, when the crosslinking agent is applied to the light-emitting layer of a light-emitting device, an imbalance of carriers characterized by a hole deficiency and an electron surplus in the light-emitting device can be improved, and the performance of the device can be enhanced.

For example, a crosslinking agent comprising imidazole, pyridine, triazine and pyrimidine can be applied either to the electron injection layer and the electron transport layer of a light-emitting device, or to the light-emitting layer of a light-emitting device. For example, when the crosslinking agent is applied to the electron injection layer and the electron transport layer of a light-emitting device, due to the electron transport properties of the crosslinking agent, the electron mobility of the electron injection layer and the electron transport layer will not decrease significantly, thereby lowering the voltage of the light-emitting device.

In one embodiment, the electroactive group includes at least one of

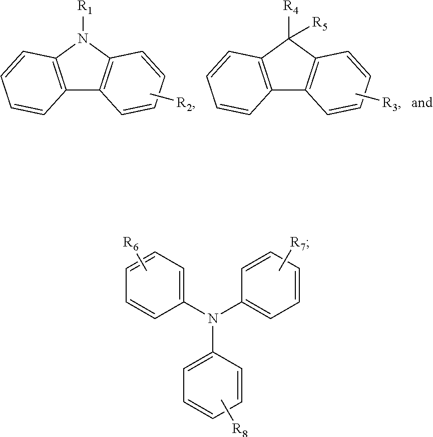

where R₁, R₂, R₃, R₄, R₅, R₆, R₇ and R₈ each independently include at least one of H, F, Cl, Br, I, CN, NO₂, a liner alkyl group having 1-40 carbon atoms, a branched alkyl group having 3-40 carbon atoms, a cyclic alkyl group having 3-40 carbon atoms, a branched alkyl group having 2-40 carbon atoms, and a cyclic amine group having 2-40 carbon atoms.

In one embodiment, at least one H atom of the linear alkyl group having 1-40 carbon atoms is substituted with F, Cl, Br, I, CN or NO₂; and/or at least one H atom of the branched alkyl group having 3-40 carbon atoms is substituted with F, Cl, Br, I, CN, or NO₂; and/or at least one H atom of the cyclic alkyl group having 3-40 carbon atoms is substituted with F, Cl, Br, I, CN, or NO₂; and/or at least one H atom of the branched alkyl group having 2-40 carbon atoms is substituted with F, Cl, Br, I, CN, or NO₂; and/or at least one H atom of the cyclic amine group having 2-40 carbon atoms is substituted with F, Cl, Br, I, CN, or NO₂; and/or at least two non-adjacent CH₂ groups of the linear alkyl group having 1-40 carbon atoms are replaced with O or S; and/or at least two non-adjacent CH₂ groups of the branched alkyl group having 3-40 carbon atoms are replaced with O or S; and/or at least two non-adjacent CH₂ groups of the cyclic alkyl group having 3-40 carbon atoms are replaced with O or S; and/or at least two non-adjacent CH₂ groups of the branched alkyl group having 2-40 carbon atoms are replaced with O or S; and/or at least two non-adjacent CH₂ groups of the cyclic amine group having 2-40 carbon atoms are replaced with O or S. This, in turn, is beneficial for enhancing the electron/hole transport properties of the crosslinking agent.

In one embodiment, the crosslinking group 200 includes a photocrosslinking group.

For example, the raw materials of a hole injection layer comprise the crosslinking agent and conventional raw materials of a hole injection layer, the hole injection material layer as a whole is prepared using an evaporation method, the hole injection material layer is irradiated with ultraviolet light, and the UV-irradiated hole injection material layer is developed using a developer to obtain a hole injection layer. It can be understood that, when the hole injection material layer is irradiated with ultraviolet light, the crosslinking group 200 undergoes crosslinking with the conventional raw materials of a hole injection layer under the ultraviolet irradiation, and the UV-irradiated hole injection material layer can resist the etching of a developer, and in contrast, the hole injection material layer that is not exposed to ultraviolet light cannot resist the etching of the developer and thus is etched away. In this way, the hole injection material layer is patterned, and a hole injection layer is obtained.

For example, the raw materials of a hole transport layer comprise the crosslinking agent and conventional raw materials of a hole transport layer, the hole transport material layer as a whole is prepared using an evaporation method, the hole transport material layer is irradiated with ultraviolet light, and the UV-irradiated hole transport material layer is developed using a developer to obtain a hole transport layer. It can be understood that, when the hole transport material layer is irradiated with ultraviolet light, the crosslinking group 200 undergoes crosslinking with the conventional raw materials of a hole transport layer under the ultraviolet irradiation, and the UV-irradiated hole transport material layer can resist the etching of a developer, and in contrast, the hole transport material layer that is not exposed to ultraviolet light cannot resist the etching of the developer and thus is etched away. In this way, the hole transport material layer is patterned, and a hole transport layer is obtained.

For example, the raw materials of a light-emitting layer comprise the crosslinking agent and conventional raw materials of a light-emitting layer, the light-emitting material layer as a whole is prepared using an evaporation method, the light-emitting material layer is irradiated with ultraviolet light, and the UV-irradiated light-emitting material layer is developed using a developer to obtain a light-emitting layer. It can be understood that, when the light-emitting material layer is irradiated with ultraviolet light, the crosslinking group 200 undergoes crosslinking with the conventional raw materials of a light-emitting layer under the ultraviolet irradiation, and the UV-irradiated light-emitting material layer can resist the etching of a developer, and in contrast, the light-emitting material layer that is not exposed to ultraviolet light cannot resist the etching of the developer and thus is etched away. In this way, the light-emitting material layer is patterned, and a light-emitting layer is obtained.

It can be understood that, the number of the crosslinking groups in the same crosslinking agent molecular structure is greater than or equal to 2. Thus, it is convenient for the crosslinking of the crosslinking agent with other organic materials.

In one embodiment, the crosslinking group includes at least one of

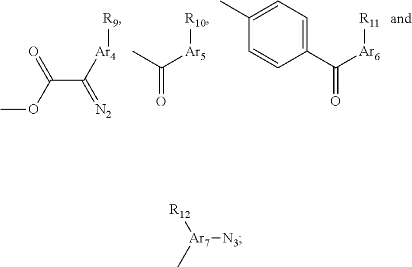

where Ar₄, Ar₅, Ar₆, and Ar₇ each independently include an aromatic or heteroaromatic ring; R₉, R₁₀, R₁₁ and R₁₂ each independently include at least one of H, F, Cl, Br, I, CN, NO₂, a liner alkyl group having 1-40 carbon atoms, a branched alkyl group having 3-40 carbon atoms, a cyclic alkyl group having 3-40 carbon atoms, a branched alkyl group having 2-40 carbon atoms, and a cyclic amine group having 2-40 carbon atoms. Thus, the structure of the crosslinking group is of an appropriate size, which is beneficial for hole hopping to or out of the electroactive group, enhancing the hole transport performance of the light-emitting device, thereby helping to lower the voltage of the light-emitting device and improve the performance thereof. Moreover, the above-described crosslinking groups exhibit an excellent crosslinking effect under ultraviolet light irradiation.

In one embodiment, at least one H atom of the linear alkyl group having 1-40 carbon atoms is substituted with F, Cl, Br, I, CN or NO₂; and/or at least one H atom of the branched alkyl group having 3-40 carbon atoms is substituted with F, Cl, Br, I, CN, or NO₂; and/or at least one H atom of the cyclic alkyl group having 3-40 carbon atoms is substituted with F, Cl, Br, I, CN, or NO₂; and/or at least one H atom of the branched alkyl group having 2-40 carbon atoms is substituted with F, Cl, Br, I, CN, or NO₂; and/or at least one H atom of the cyclic amine group having 2-40 carbon atoms is substituted with F, Cl, Br, I, CN, or NO₂; and/or at least two non-adjacent CH₂ groups of the linear alkyl group having 1-40 carbon atoms are replaced with O or S; and/or at least two non-adjacent CH₂ groups of the branched alkyl group having 3-40 carbon atoms are replaced with O or S; and/or at least two non-adjacent CH₂ groups of the cyclic alkyl group having 3-40 carbon atoms are replaced with O or S; and/or at least two non-adjacent CH₂ groups of the branched alkyl group having 2-40 carbon atoms are replaced with O or S; and/or at least two non-adjacent CH₂ groups of the cyclic amine group having 2-40 carbon atoms are replaced with O or S. Thus, the crosslinking agent has superior crosslinking performance.

In one embodiment, the crosslinking agent comprises a structure represented by formula (1):

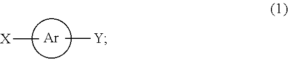

wherein the electroactive group includes Ar, and the crosslinking group includes X and Y,
where Ar includes a structure represented by at least one of formulae (1-1) to (1-3):

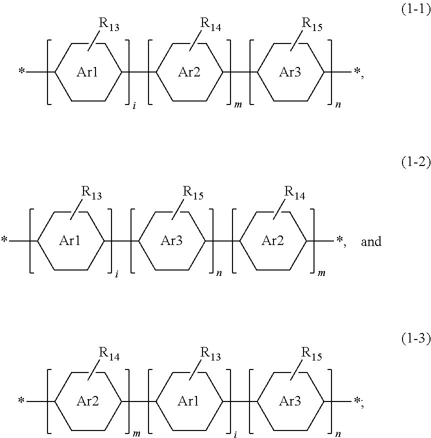

in formulae (1-1) to (1-3), * represents a bonding site for X and Y;
X is bonded to at least one site of the site represented by * and a site on Ar1 to Ar3 and R₁₃ to R₁₅, and/or Y is bonded to at least one site of the site represented by * and a site on Ar1 to Ar3 and R₁₃ to R₁₅;
where Ar1, Ar2, and Ar3 each independently include at least one of

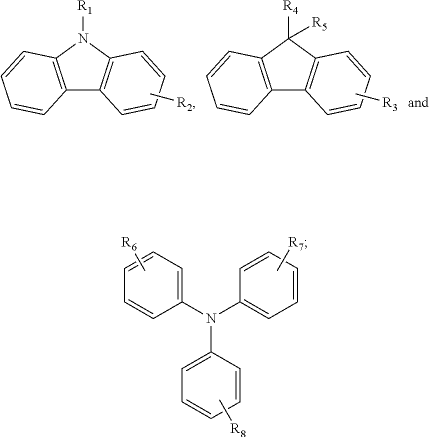

X and Y each independently include at least one of

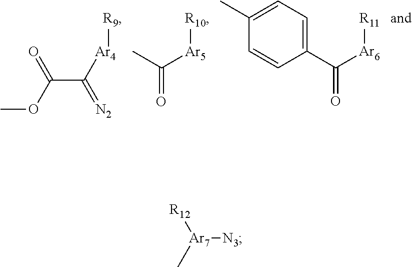

wherein R₁, R₂, R₃, R₄, R₅, R₆, R₇, R₈, R₉, R₁₀, R₁₁, R₁₂, R₁₃, R₁₄ and R₁₅ each independently include at least one of H, F, Cl, Br, I, CN, NO₂, a liner alkyl group having 1-40 carbon atoms, a branched alkyl group having 3-40 carbon atoms, a cyclic alkyl group having 3-40 carbon atoms, a branched alkyl group having 2-40 carbon atoms, and a cyclic amine group having 2-40 carbon atoms; and Ar₄, Ar₅, Ar₆, and Ar₇ each independently include an aromatic or heteroaromatic ring; the number of R₁₃, R₁₄ and R₁₅ is each independently at least one; and i+m+n≤18 (for example, 1, 2, 4, 6, 8, 10, 12, 14, 16, or 18, etc.), and i, m, and n are not all 0.

For example, Ar₁, Ar₂, and Ar₃ may have the same or different structural formulae. For example, i, m, and n are not all 0, including the following cases: one of i, m and n is not 0; two of i, m and n are not 0; and three of i, m and n are not 0.

In one embodiment, i+m+n≤9.

In one embodiment, at least one H atom of the linear alkyl group having 1-40 carbon atoms is substituted with F, Cl, Br, I, CN or NO₂; and/or at least one H atom of the branched alkyl group having 3-40 carbon atoms is substituted with F, Cl, Br, I, CN, or NO₂; and/or at least one H atom of the cyclic alkyl group having 3-40 carbon atoms is substituted with F, Cl, Br, I, CN, or NO₂; and/or at least one H atom of the branched alkyl group having 2-40 carbon atoms is substituted with F, Cl, Br, I, CN, or NO₂; and/or at least one H atom of the cyclic amine group having 2-40 carbon atoms is substituted with F, Cl, Br, I, CN, or NO₂; and/or at least two non-adjacent CH₂ groups of the linear alkyl group having 1-40 carbon atoms are replaced with O or S; and/or at least two non-adjacent CH₂ groups of the branched alkyl group having 3-40 carbon atoms are replaced with O or S; and/or at least two non-adjacent CH₂ groups of the cyclic alkyl group having 3-40 carbon atoms are replaced with O or S; and/or at least two non-adjacent CH₂ groups of the branched alkyl group having 2-40 carbon atoms are replaced with O or S; and/or at least two non-adjacent CH₂ groups of the cyclic amine group having 2-40 carbon atoms are replaced with O or S. For example, the number of X and Y may be the same or different in the same crosslinking agent molecular structure. X and Y may have the same or different structural formulae.

For example, in the same crosslinking agent molecular structure, a plurality of X and a plurality of Y can be included. In one embodiment, the sum of the number of X and the number of Y in the same crosslinking agent molecular structure is greater than or equal to 2 and less than or equal to 20 (e.g., 2, 4, 6, 8, 10, 12, 14, 16, 18 or 20, etc.). In one embodiment, the sum of the number of X and the number of Y is greater than or equal to 2 and less than or equal to 8. Thus, in the same crosslinking agent molecular structure, when the number of the crosslinking groups is appropriate, the crosslinking performance is excellent, with essentially no impact on hole hopping to or out of the electroactive group.

In one embodiment, the crosslinking agent comprises a structure represented by at least one of formulae (2-1) to (2-36):

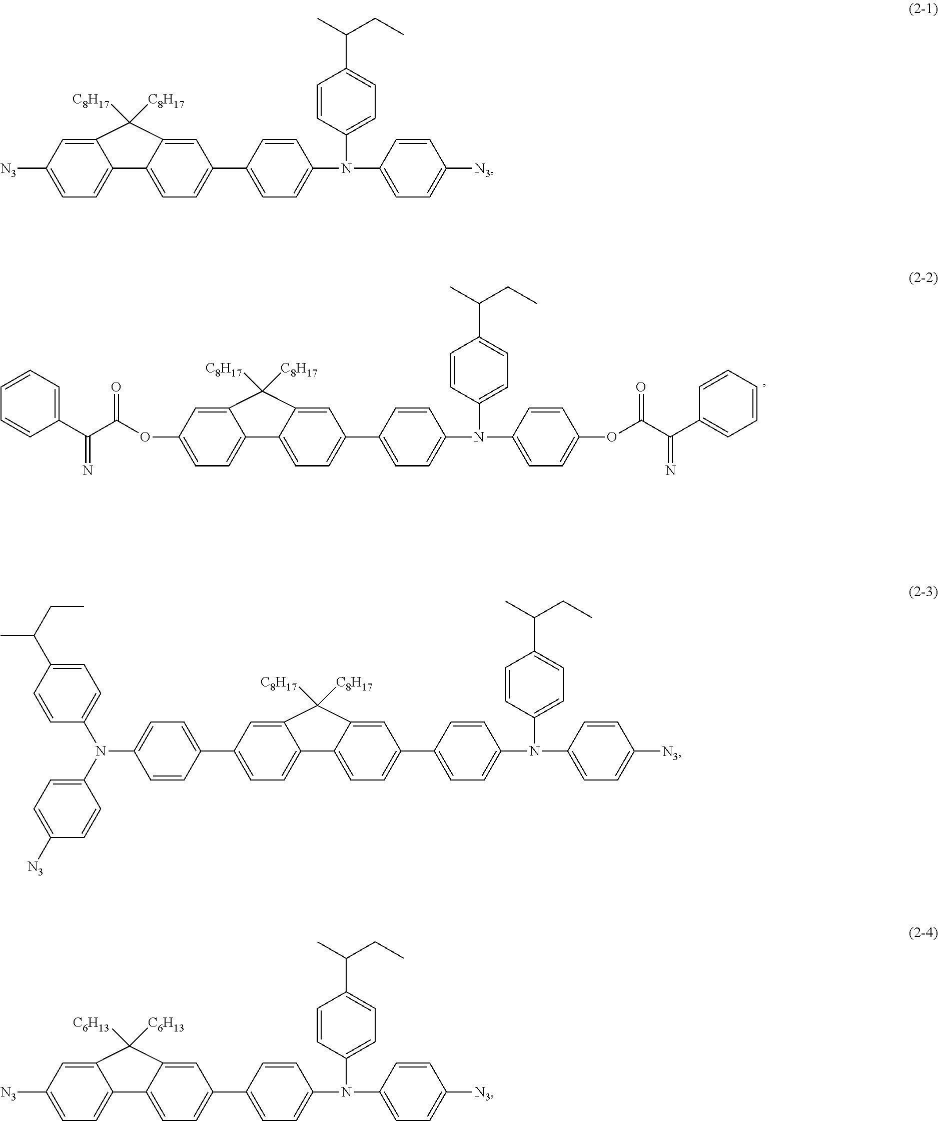

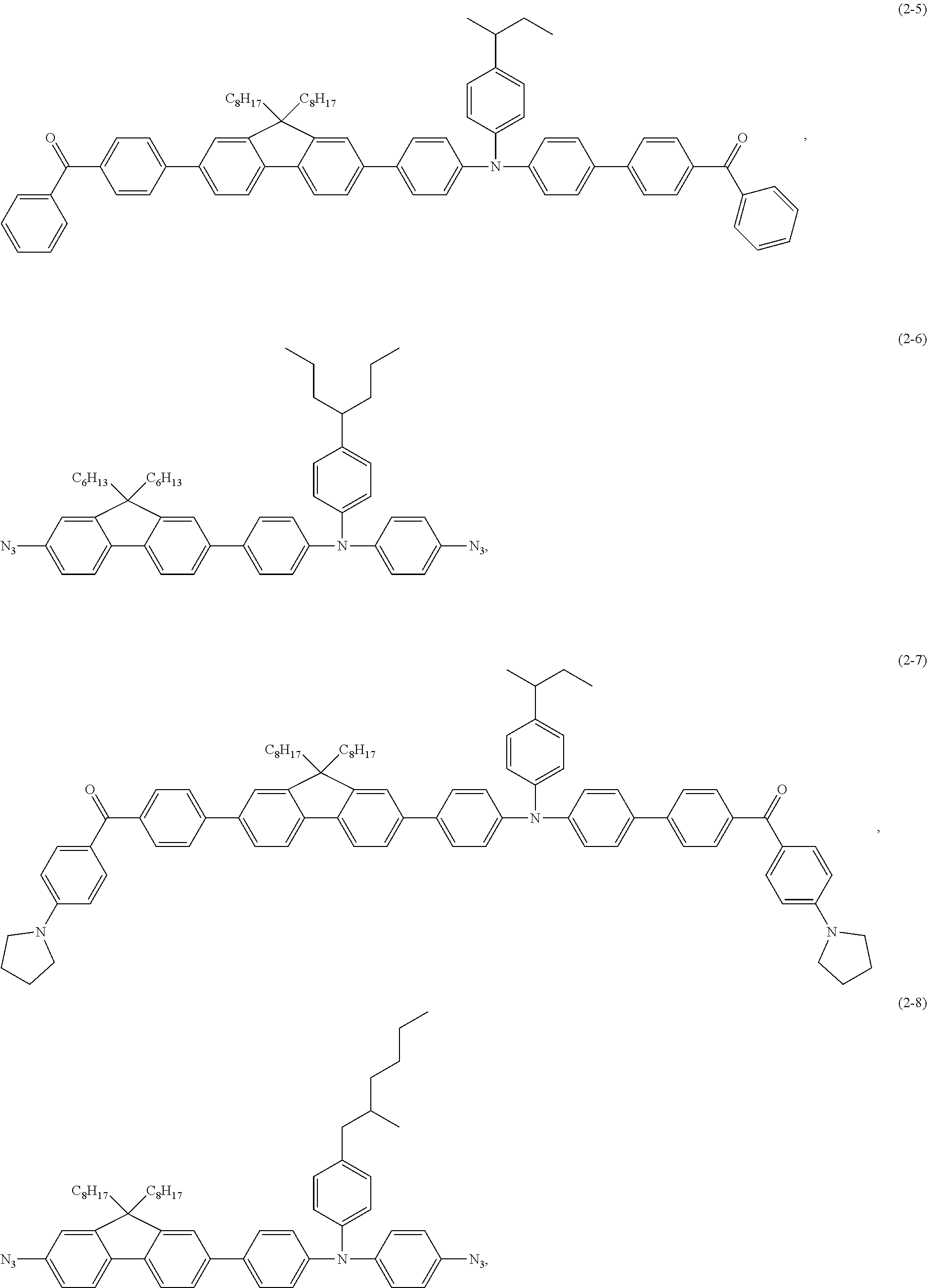

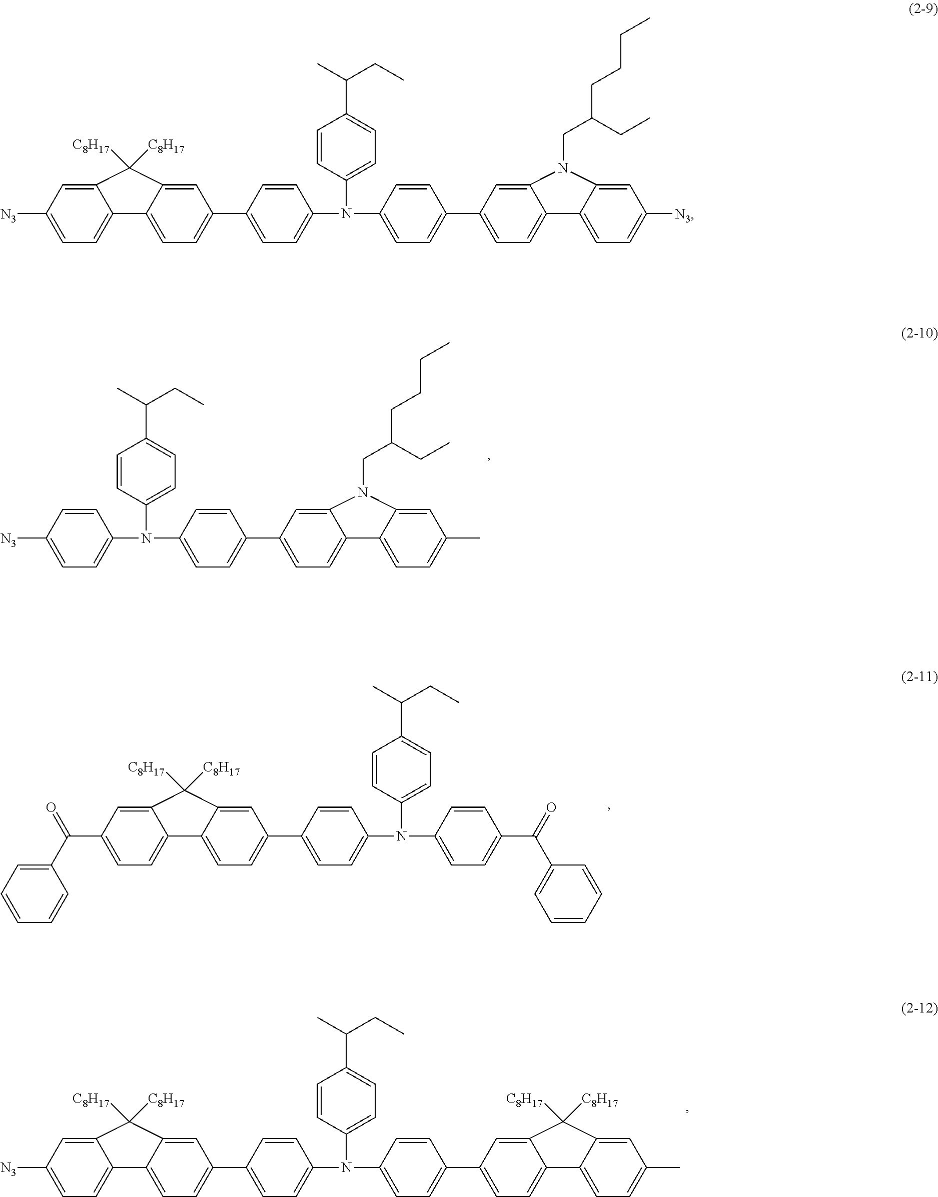

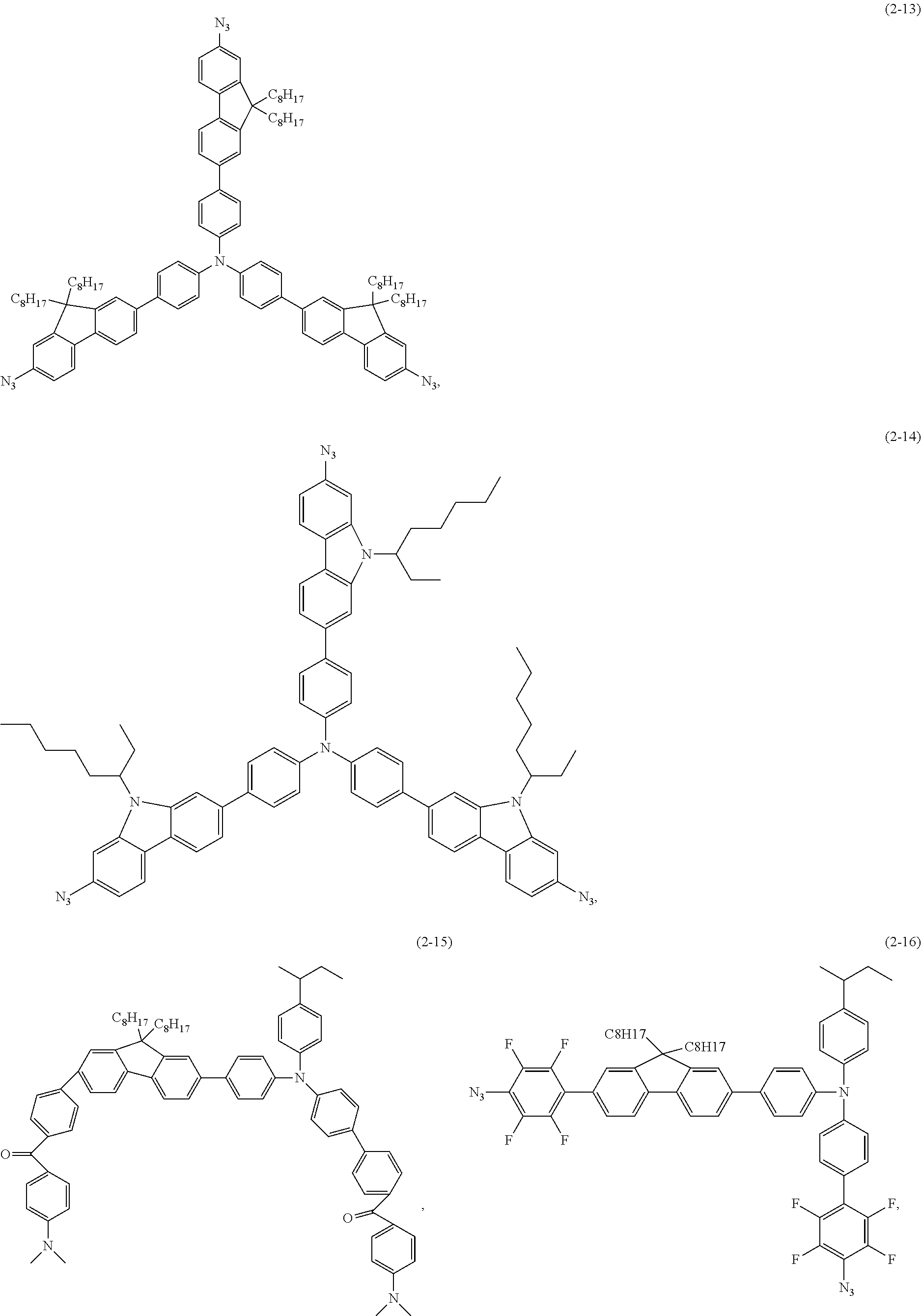

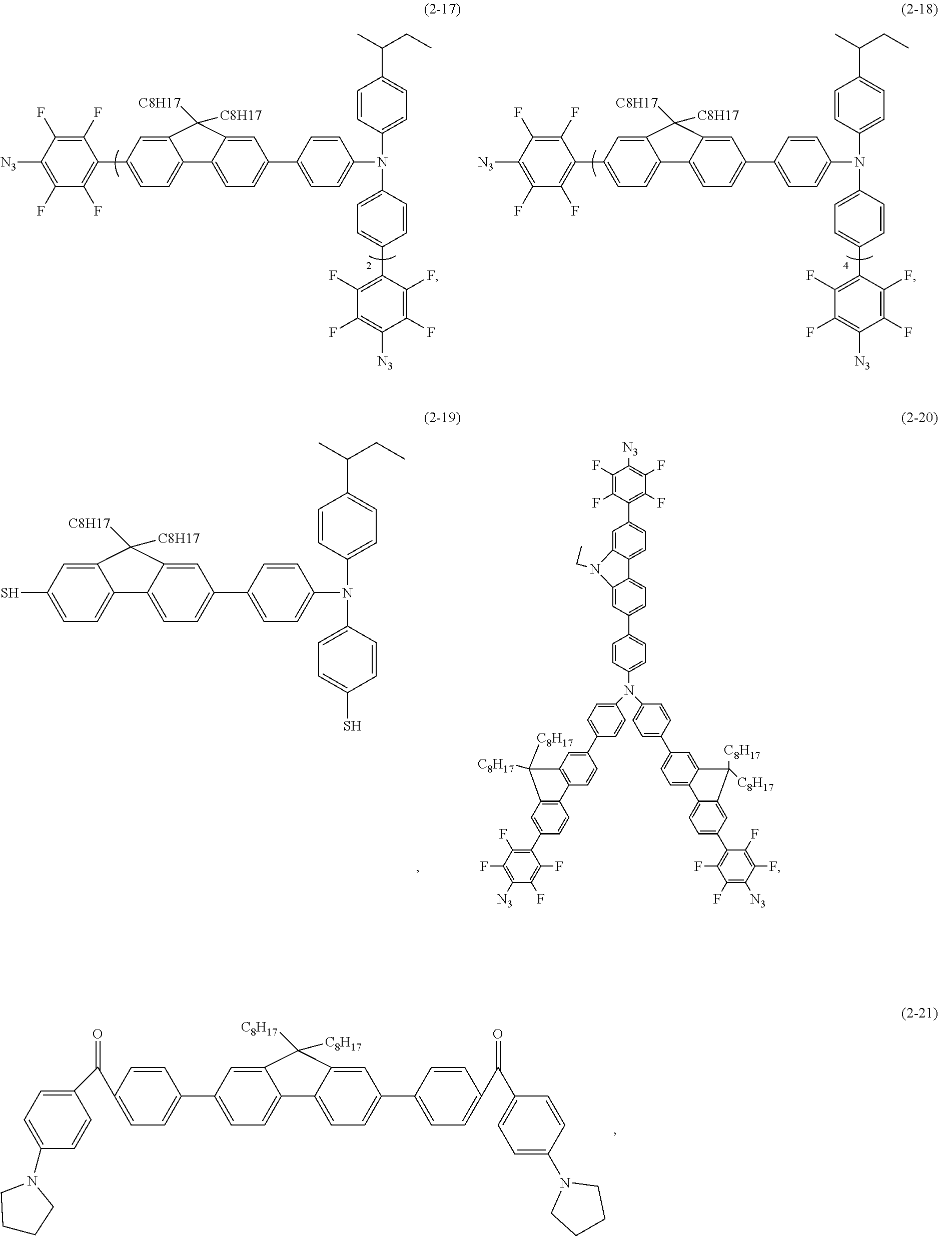

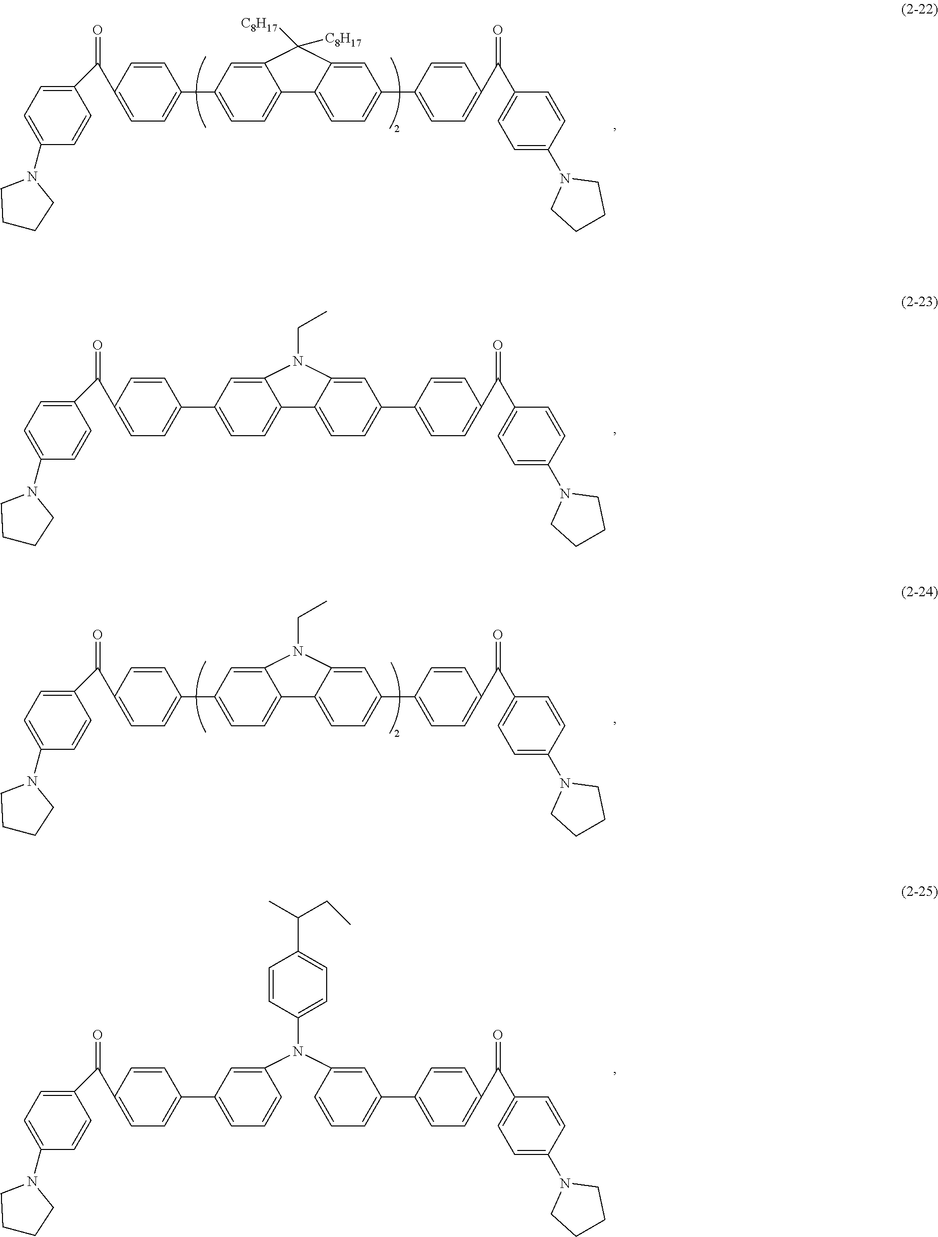

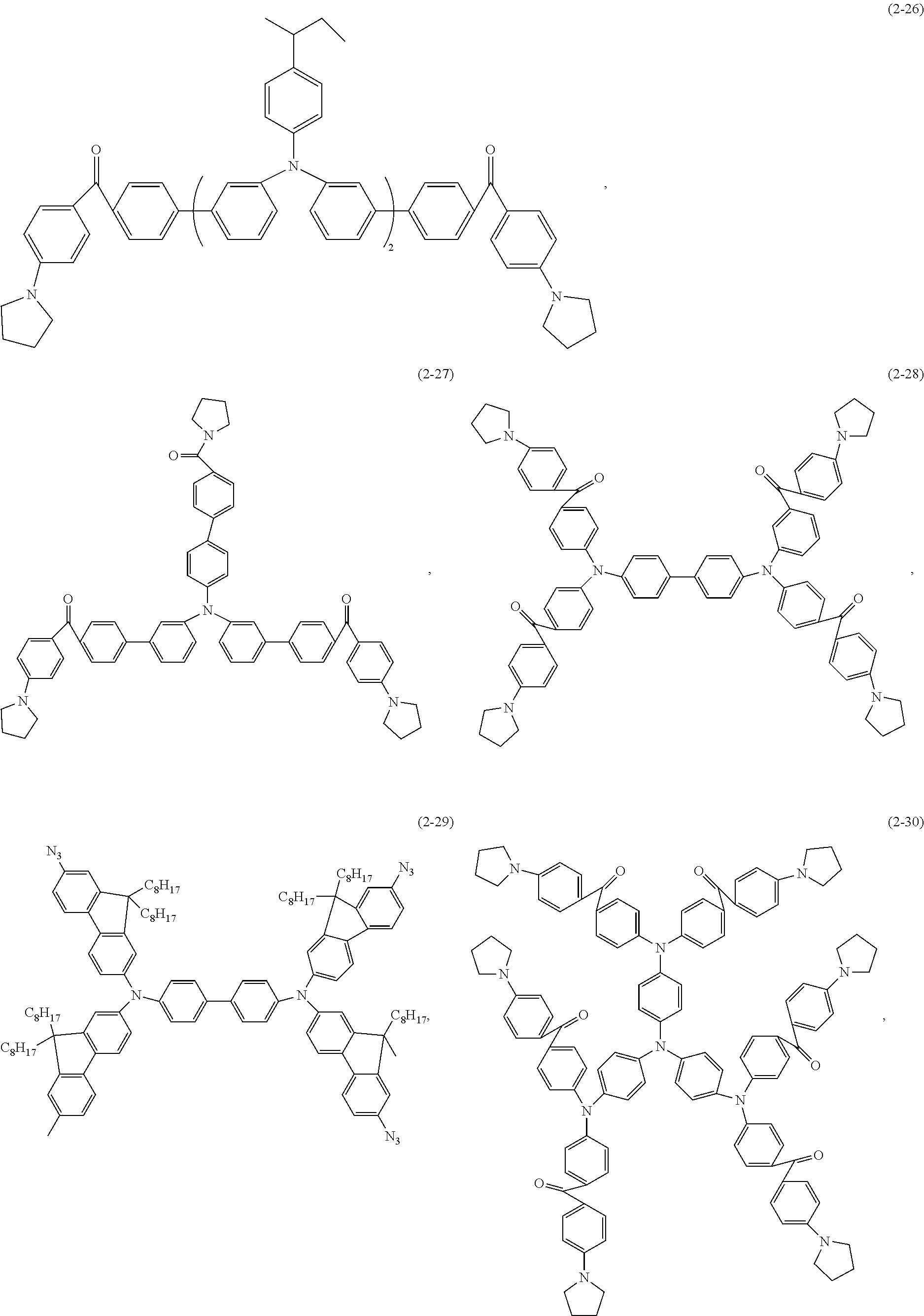

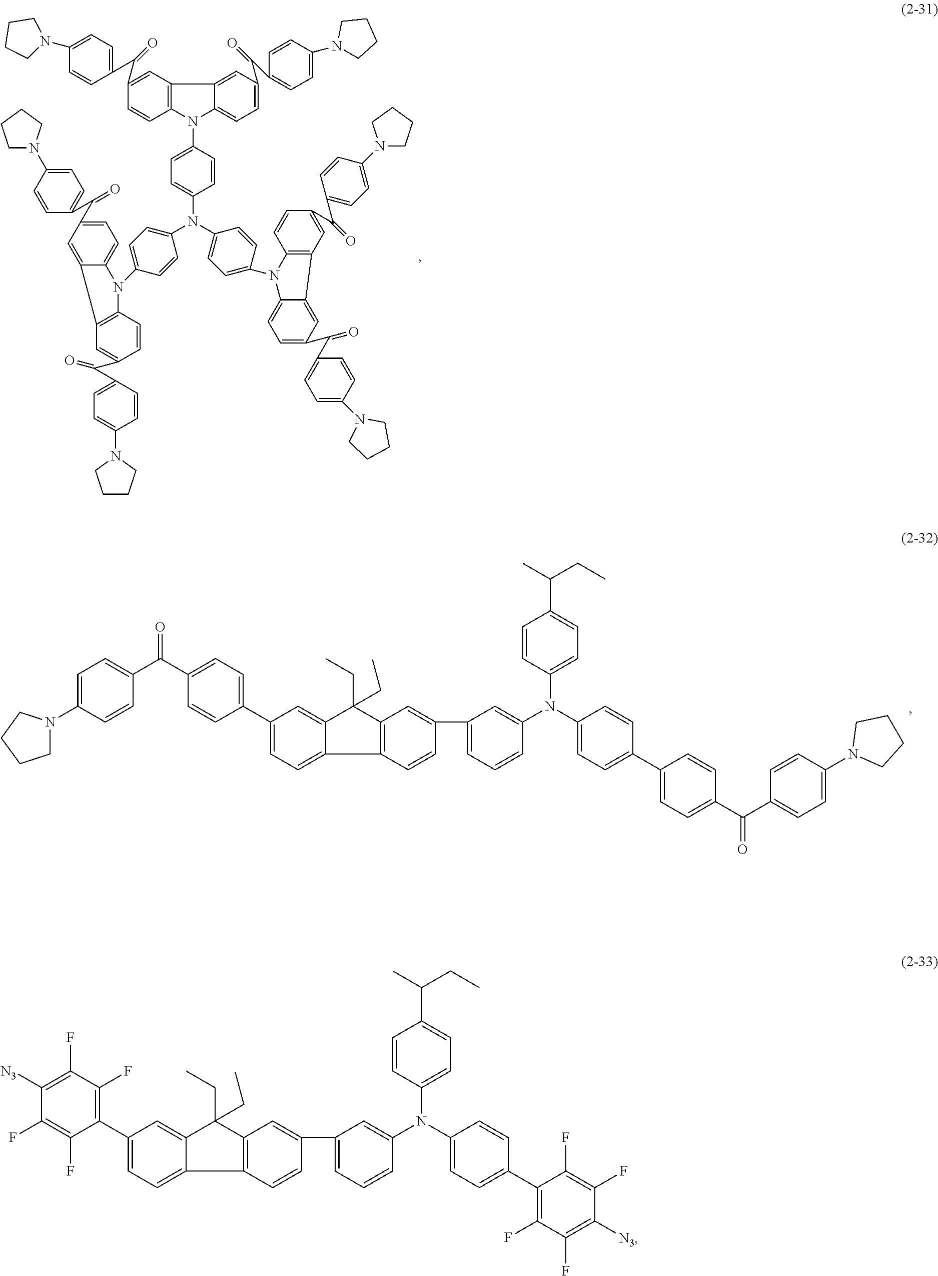

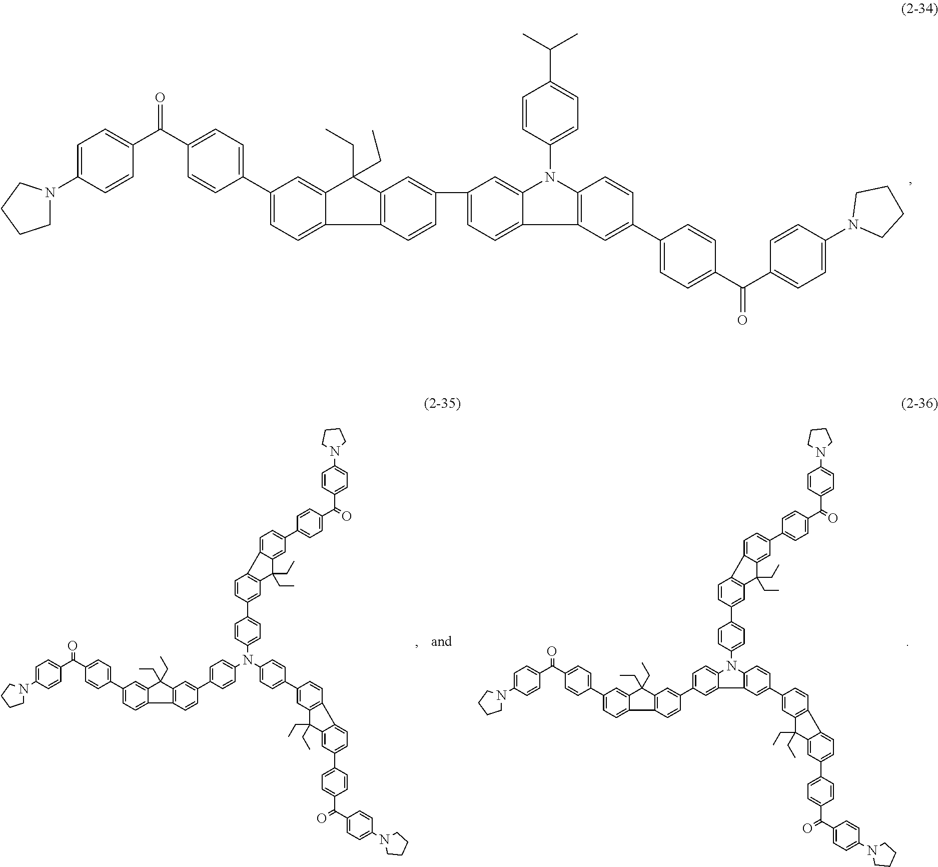

Thus, the crosslinking agent above has relatively strong electrical activity, which is beneficial for hole hopping to or out of the electroactive group, enhancing the hole transport performance of the light-emitting device, thereby helping to lower the voltage of the light-emitting device and improve the performance thereof. Moreover, the above-described crosslinking groups exhibit an excellent crosslinking effect under ultraviolet light irradiation.

The crosslinking agents used in the prior art do not have electrical activity, and when they are applied to a hole injection layer and a hole transport layer, the hole mobility of the hole injection layer and the hole transport layer drops significantly, and the voltage of the light-emitting device is relatively high, leading to high energy consumption. In the present application, when the crosslinking agent in an embodiment of the present application is applied to the hole injection layer and the hole transport layer of a light-emitting device, due to the hole transport properties of the crosslinking agent, the hole mobility of the hole injection layer and the hole transport layer will not decrease significantly, thereby lowering the voltage of the light-emitting device. For example, when the crosslinking agent is applied to the light-emitting layer of a light-emitting device, an imbalance of carriers characterized by a hole deficiency and an electron surplus in the light-emitting device can be improved, and the performance of the device can be enhanced.

One embodiment of the present application provides a method for preparing a crosslinking agent, including: subjecting a first compound and a second compound to a coupling reaction to obtain a crosslinking agent comprising an electroactive group and a crosslinking group that are bonded, with the crosslinking group being located on at least a portion of the periphery of the electroactive group; wherein the first compound comprises an electroactive group and the second compound comprises a crosslinking group; or, the electroactive group comprises a first sub-electroactive group and a second sub-electroactive group, and the crosslinking group comprises a first sub-crosslinking group and a second sub-crosslinking group, and the first compound comprises a first sub-electroactive group and a first sub-crosslinking group, and the second compound comprises a second sub-electroactive group and a second sub-crosslinking group; or, the first compound comprises an electroactive group and a first sub-crosslinking group, and the second compound comprises a second sub-crosslinking group; or, the first compound comprises a crosslinking group and a first sub-electroactive group, and the second compound comprises a second sub-electroactive group.

For example, the first compound includes, but is not limited to

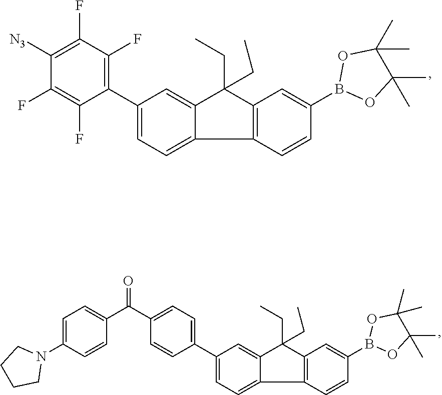 [SMILES: CCC1(CC)c2cc(B3OC(C)(C)C(C)(C)O3)ccc2-c2ccc(-c3c(F)c(F)c(N=[N+]=[N-])c(F)c3F)cc21 ; CCC1(CC)c2cc(B3OC(C)(C)C(C)(C)O3)ccc2-c2ccc(-c3ccc(C(=O)c4ccc(N5CCCC5)cc4)cc3)cc21]

etc.; and the second compound includes, but is not limited to

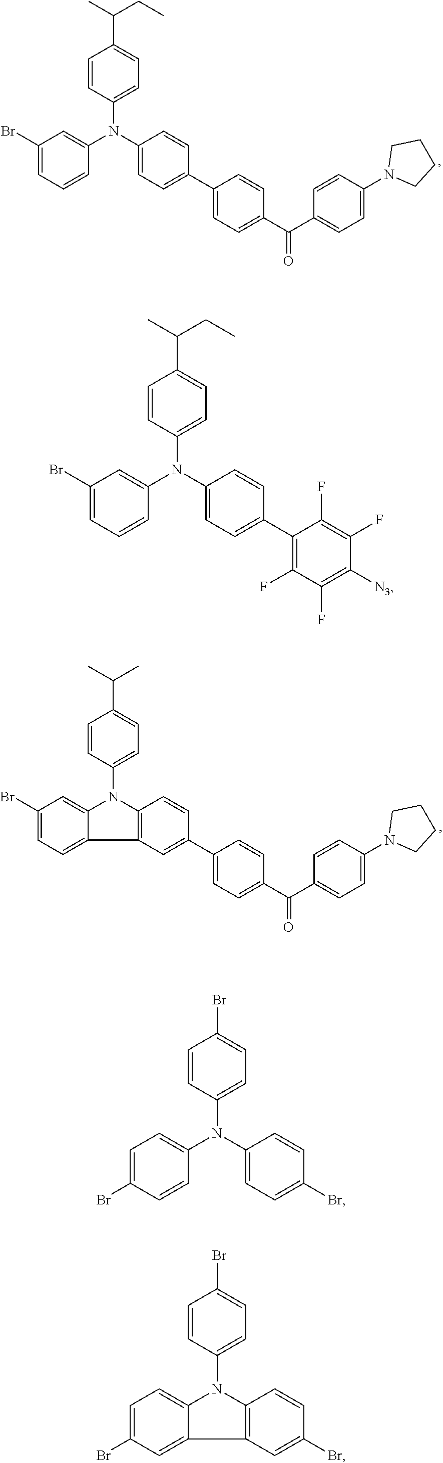 [SMILES: CCC(C)c1ccc(N(c2ccc(-c3ccc(C(=O)c4ccc(N5CCCC5)cc4)cc3)cc2)c2cccc(Br)c2)cc1 ; CCC(C)c1ccc(N(c2ccc(-c3c(F)c(F)c(N=[N+]=[N-])c(F)c3F)cc2)c2cccc(Br)c2)cc1 ; CC(C)c1ccc(-n2c3ccc(-c4ccc(C(=O)c5ccc(N6CCCC6)cc5)cc4)cc3c3ccc(Br)cc32)cc1 ; Brc1ccc(N(c2ccc(Br)cc2)c2ccc(Br)cc2)cc1 ; Brc1ccc(-n2c3ccc(Br)cc3c3cc(Br)ccc32)cc1]

etc.

For example, the coupling reaction includes, but is not limited to, a Suzuki-Miyaura coupling reaction. It can be understood that, the Suzuki-Miyaura coupling reaction can also be referred to as the Suzuki coupling reaction. For example, the preparation method for the crosslinking agent comprises the following steps: mixing a first compound and a second compound (the molar ratio of the first compound to the second compound may be (1-2):(1-2)), and using a mixed system of tetrahydrofuran, ethanol and deionized water as a solvent, using Na₂CO₃ and Pd(PPh₃)₄ as a catalyst, and under nitrogen protection, heating same (the heating temperature may be 50-70° C.) for a reaction for a period of time to obtain the crosslinking agent.

For example, the preparation method for the crosslinking agent with structural formula 2-32 is as follow: in a 500 mL round-bottom flask,

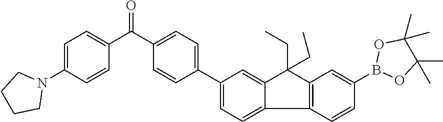 [SMILES: CCC1(CC)c2cc(B3OC(C)(C)C(C)(C)O3)ccc2-c2ccc(-c3ccc(C(=O)c4ccc(N5CCCC5)cc4)cc3)cc21]

(8.48 mmol, 1 eq) and

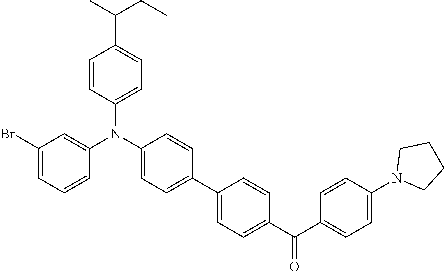 [SMILES: CCC(C)c1ccc(N(c2ccc(-c3ccc(C(=O)c4ccc(N5CCCC5)cc4)cc3)cc2)c2cccc(Br)c2)cc1]

(9.34 mmol, 1.1 eq) are added, a mixed system of tetrahydrofuran (160 ml), ethanol (60 mL), and deionized water (100 mL) is used as a solvent, Na₂CO₃ (67.84 mmol, 8 eq) and Pd(PPh₃)₄ (1.27 mmol, 0.15 eq) are added as a catalyst, and the mixture is heated under nitrogen protection to 60° C. for a reaction in the absence of light for 36 hours; upon cooling, the reaction system is filtered, and the filter cake is successively washed with saturated brine and ethanol and further treated by conventional methods to obtain the crosslinking agent (71% yield, 99.56% purity by HPLC analysis). Mass spectrometric analysis (MALDI-TOF-MS) results: m/z: 1019.75. Elemental analysis results: theoretical values (%): C, 85.93; H, 6.82; N, 4.12; and O, 3.14. Experimental values (%): C, 85.73; H, 6.60; N, 4.42; and O, 3.26.

For example, the preparation method for the crosslinking agent with structural formula 2-33 is as follow: in a 500 mL round-bottom flask,

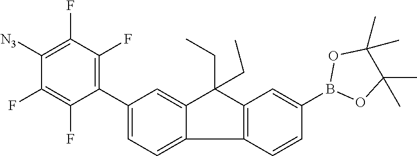 [SMILES: CCC1(CC)c2cc(B3OC(C)(C)C(C)(C)O3)ccc2-c2ccc(-c3c(F)c(F)c(N=[N+]=[N-])c(F)c3F)cc21]

(8.48 mmol, 1 eq) and

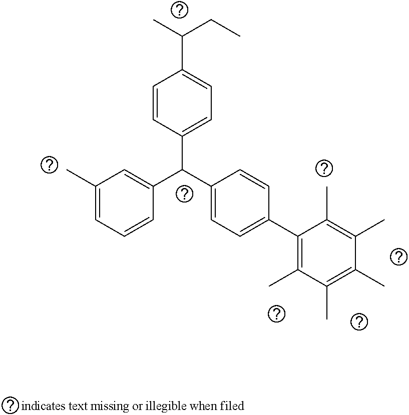

(9.34 mmol, 1.1 eq) are added, a mixed system of tetrahydrofuran (160 ml), ethanol (60 mL), and deionized water (100 mL) is used as a solvent, Na₂CO₃ (67.84 mmol, 8 eq) and Pd(PPh₃)₄ (1.27 mmol, 0.15 eq) are added as a catalyst, and the mixture is heated under nitrogen protection to 60° C. for a reaction in the absence of light for 36 hours; upon cooling, the reaction system is filtered, and the filter cake is successively washed with saturated brine and ethanol and further treated by conventional methods to obtain the crosslinking agent (76% yield, 99.66% purity by HPLC analysis). MALDI-TOF-MS results: m/z: 889.61. Elemental analysis results: theoretical values (%): C, 68.07; H, 4.14; F, 16.89; and N, 10.90. Experimental values (%): C, 68.05; H, 4.16; F, 16.79; and N, 11.00.

For example, the preparation method for the crosslinking agent with structural formula 2-34 is as follow: in a 500 mL round-bottom flask,

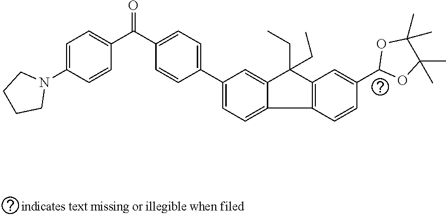 [SMILES: CCC1(CC)c2cc(-c3ccc(C(=O)c4ccc(N5CCCC5)cc4)cc3)ccc2-c2ccc(C3OC(C)(C)C(C)(C)O3)cc21]

(8.48 mmol, 1 eq) and

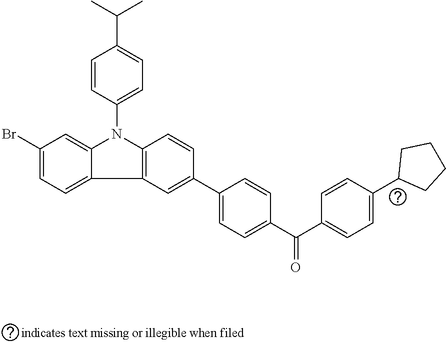 [SMILES: CC(C)c1ccc(-n2c3ccc(-c4ccc(C(=O)c5ccc(C6CCCC6)cc5)cc4)cc3c3ccc(Br)cc32)cc1]

(9.34 mmol, 1.1 eq) are added, a mixed system of tetrahydrofuran (160 ml), ethanol (60 mL), and deionized water (100 mL) is used as a solvent, Na₂CO₃ (67.84 mmol, 8 eq) and Pd(PPh₃)₄ (1.27 mmol, 0.15 eq) are added as a catalyst, and the mixture is heated under nitrogen protection to 60° C. for a reaction in the absence of light for 36 hours; upon cooling, the reaction system is filtered, and the filter cake is successively washed with saturated brine and ethanol and further treated by conventional methods to obtain the crosslinking agent (85% yield, 99.33% purity by HPLC analysis). MALDI-TOF-MS results: m/z: 1003.71. Elemental analysis results: theoretical values (%): C, 86.11; H, 6.52; N, 4.18; and O, 3.19. Experimental values (%): C, 86.11; H, 6.67; N, 4.11; and O, 3.11.

For example, the process for preparing the crosslinking agent with structural formula 2-35 is as follow: in a 500 mL round-bottom flask,

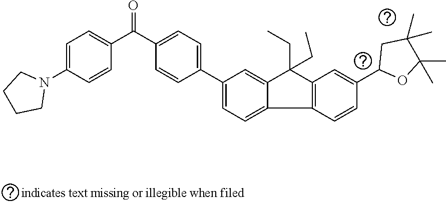 [SMILES: CCC1(CC)c2cc(-c3ccc(C(=O)c4ccc(N5CCCC5)cc4)cc3)ccc2-c2ccc(C3CC(C)(C)C(C)(C)O3)cc21]

(33.92 mmol, 4 eq) and

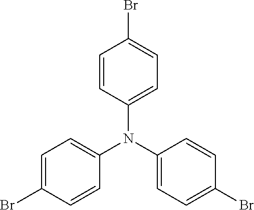 [SMILES: Brc1ccc(N(c2ccc(Br)cc2)c2ccc(Br)cc2)cc1]

(8.48 mmol, 1 eq) are added, a mixed system of tetrahydrofuran (160 ml), ethanol (60 mL), and deionized water (100 mL) is used as a solvent, Na₂CO₃ (67.84 mmol, 8 eq) and Pd(PPh₃)₄ (1.27 mmol, 0.15 eq) are added as a catalyst, and the mixture is heated under nitrogen protection to 60° C. for a reaction in the absence of light for 36 hours; upon cooling, the reaction system is filtered, and the filter cake is successively washed with saturated brine and ethanol and further treated by conventional methods to obtain the crosslinking agent (62% yield, 99.13% purity by HPLC analysis). MALDI-TOF-MS results: m/z: 1653.93. Elemental analysis results: Theoretical values (%): C, 87.13; H, 6.58; N, 3.39; O, 2.90. Experimental values (%): C, 87.10; H, 6.48; N, 3.49; O, 3.03.

For example, the preparation method for the crosslinking agent with structural formula 2-36 is as follow: in a 500 mL round-bottom flask,

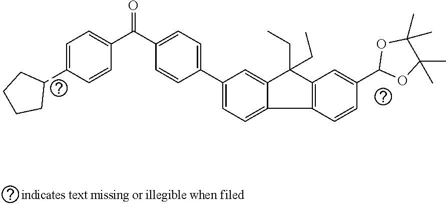 [SMILES: CCC1(CC)c2cc(-c3ccc(C(=O)c4ccc(C5CCCC5)cc4)cc3)ccc2-c2ccc(C3OC(C)(C)C(C)(C)O3)cc21]

(33.92 mmol, 4 eq) and

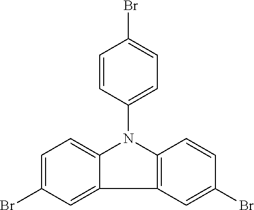 [SMILES: Brc1ccc(-n2c3ccc(Br)cc3c3cc(Br)ccc32)cc1]

(8.48 mmol, 1 eq) are added, a mixed system of tetrahydrofuran (160 ml), ethanol (60 mL), and deionized water (100 mL) is used as a solvent, Na₂CO₃ (67.84 mmol, 8 eq) and Pd(PPh₃)₄ (1.27 mmol, 0.15 eq) are added as a catalyst, and the mixture is heated under nitrogen protection to 60° C. for a reaction in the absence of light for 36 hours; upon cooling, the reaction system is filtered, and the filter cake is successively washed with saturated brine and ethanol and further treated by conventional methods to obtain the crosslinking agent (51% yield, 99.09% purity by HPLC analysis). MALDI-TOF-MS results: m/z: 1651.22. Elemental analysis results: Theoretical values (%): C, 87.24; H, 6.47; N, 3.39; O, 2.91. Experimental values (%): C, 87.05; H, 6.53; N, 3.52; O, 3.00.

It can be understood that the crosslinking agents with structural formulae 2-1 to 2-31 can be prepared using a method with reference to the preparation methods shown in the above examples, and the ratio of raw materials, the selected solvent, the heating temperature, etc., can be selected according to actual conditions.

One embodiment of the present application provides a light-emitting device. With reference to the structural schematic diagram of a light-emitting device shown in FIG. 2, the light-emitting device includes a first electrode layer 110, a light-emitting functional layer 120 and a second electrode layer 130 that are stacked, wherein a raw material of the light-emitting functional layer 120 includes the aforementioned crosslinking agent, or a crosslinking agent prepared using the aforementioned preparation method.

It should be noted that the crosslinking agent is consistent with the foregoing description and will not be elaborated here.

For example, one of the first electrode layer 110 and the second electrode layer 130 is an anode, and the other of the first electrode layer 110 and the second electrode layer 130 is a cathode.

It should be noted that the number of layers of the light-emitting functional layer 120 is at least one light-emitting layer 124 (EML). With reference to the structural schematic diagram of a light-emitting device shown in FIG. 3, the light-emitting functional layer 120 may also include at least one of a hole injection layer 121 (HIL), a hole transport layer 122 (HTL), and an electron blocking layer 123 (EBL) that are located between the anode and the light-emitting layer 124 (EML); and at least one of an electron injection layer 125 (EIL), an electron transport layer 126 (ETL), and a hole blocking layer 127 (HBL) that are located between the cathode and the light-emitting layer 124 (EML).

For example, the number of layers the light-emitting functional layer 120 being at least one light-emitting layer 124 should be understood in a broad sense, for example, including the following cases: 1. a plurality of light-emitting layers 124 are stacked; and 2. the light-emitting functional layer 120 further comprises at least one light-emitting functional unit between the electron transport layer 126 and the electron injection layer 125, the light-emitting functional unit comprising an n-type charge generation layer, a p-type charge generation layer, a second hole transport layer, a second electron blocking layer, a second light-emitting layer, a second hole blocking layer, and a second electron transport layer that are sequentially stacked, with the n-type charge generation layer being located on the side of the p-type charge generation layer that is close to the electron transport layer 126; in this case, the second light-emitting layers in a plurality of light-emitting functional units and the light-emitting layer 124 constitute a multi-layer light-emitting layer.

In one embodiment, the light-emitting layer comprises a crosslinking agent. For example, the raw materials of a light-emitting layer comprise the crosslinking agent and conventional raw materials of a light-emitting layer, the light-emitting material layer as a whole is prepared using an evaporation method, the light-emitting material layer is irradiated with ultraviolet light, and the UV-irradiated light-emitting material layer is developed using a developer to obtain a light-emitting layer. It can be understood that, when the light-emitting material layer is irradiated with ultraviolet light, the crosslinking group 200 undergoes crosslinking with the conventional raw materials of a light-emitting layer under the ultraviolet irradiation, and the UV-irradiated light-emitting material layer can resist the etching of a developer, and in contrast, the light-emitting material layer that is not exposed to ultraviolet light cannot resist the etching of the developer and thus is etched away. In this way, the light-emitting material layer is patterned, and a light-emitting layer is obtained. When the crosslinking agent is applied to the light-emitting layer of a light-emitting device, an imbalance of carriers characterized by a hole deficiency and an electron surplus in the light-emitting device can be improved, and the performance of the device can be enhanced.

In one embodiment, the mass of the crosslinking agent is 1-30% of the total mass of the light-emitting layer (for example, 1%, 5%, 10%, 15%, 20%, 25%, or 30%, etc.). Thus, an appropriate content of the crosslinking agent in the light-emitting layer can improve the imbalance of carriers characterized by a hole deficiency and an electron surplus in the light-emitting device and enhance the performance of the device.

In one embodiment, the light-emitting layer comprises a quantum dot light-emitting layer. Thus, the light-emitting device has advantages such as a high color gamut, a long potential lifetime, a good viewing angle and low cost.

In one embodiment, with reference to FIG. 3, the light-emitting functional layer 120 further comprises at least one of a hole injection layer 121, a hole transport layer 122, and an electron blocking layer 123 that are located between the first electrode layer 110 and the light-emitting layer 124.

In one embodiment, at least one of the hole injection layer 121, the hole transport layer 122, and the electron blocking layer 123 comprises a crosslinking agent, and the crosslinking agent has an electroactive group including at least one of fluorene, carbazole, and aniline. Thus, it is conducive to the transport of holes in the light-emitting device. In one embodiment, the hole injection layer comprises a crosslinking agent. For example, the raw materials of a hole injection layer comprise the crosslinking agent and conventional raw materials of a hole injection layer, the hole injection material layer as a whole is prepared using an evaporation method, the hole injection material layer is irradiated with ultraviolet light, and the UV-irradiated hole injection material layer is developed using a developer to obtain a hole injection layer. It can be understood that, when the hole injection material layer is irradiated with ultraviolet light, the crosslinking group undergoes crosslinking with the conventional raw materials of a hole injection layer under the ultraviolet irradiation, and the UV-irradiated hole injection material layer can resist the etching of a developer, and in contrast, the hole injection material layer that is not exposed to ultraviolet light cannot resist the etching of the developer and thus is etched away. In this way, the hole injection material layer is patterned, and a hole injection layer is obtained. Due to the hole transport properties of the crosslinking agent, the hole mobility of the hole injection layer will not decrease significantly, thereby lowering the voltage of the light-emitting device.

For example, the mass of the crosslinking agent is 1-30% of the total mass of the hole injection layer (for example, 1%, 5%, 10%, 15%, 20%, 25%, or 30%, etc.). Therefore, with an appropriate content of the crosslinking agent, the hole mobility of the hole injection layer remains relatively high, thereby resulting in a relatively low voltage for the light-emitting device.

In one embodiment, the hole transport layer comprises a crosslinking agent. For example, the raw materials of a hole transport layer comprise the crosslinking agent and conventional raw materials of a hole transport layer, the hole transport material layer as a whole is prepared using an evaporation method, the hole transport material layer is irradiated with ultraviolet light, and the UV-irradiated hole transport material layer is developed using a developer to obtain a hole transport layer. It can be understood that, when the hole transport material layer is irradiated with ultraviolet light, the crosslinking group undergoes crosslinking with the conventional raw materials of a hole transport layer under the ultraviolet irradiation, and the UV-irradiated hole transport material layer can resist the etching of a developer, and in contrast, the hole transport material layer that is not exposed to ultraviolet light cannot resist the etching of the developer and thus is etched away. In this way, the hole transport material layer is patterned, and a hole transport layer is obtained. Due to the hole transport properties of the crosslinking agent, the hole mobility of the hole transport layer will not decrease significantly, thereby lowering the voltage of the light-emitting device.

For example, the mass of the crosslinking agent is 1-30% of the total mass of the hole transport layer (for example, 1%, 5%, 10%, 15%, 20%, 25%, or 30%, etc.). Therefore, with an appropriate content of the crosslinking agent, the hole mobility of the hole transport layer remains relatively high, thereby resulting in a relatively low voltage for the light-emitting device.

In one embodiment, the electron blocking layer comprises a crosslinking agent. For example, the raw materials of an electron blocking layer comprise the crosslinking agent and conventional raw materials of an electron blocking layer, the electron blocking material layer as a whole is prepared using an evaporation method, the electron blocking material layer is irradiated with ultraviolet light, and the UV-irradiated electron blocking material layer is developed using a developer to obtain an electron blocking layer. It can be understood that, when the electron blocking material layer is irradiated with ultraviolet light, the crosslinking group undergoes crosslinking with the conventional raw materials of an electron blocking layer under the ultraviolet irradiation, and the UV-irradiated electron blocking material layer can resist the etching of a developer, and in contrast, the electron blocking material layer that is not exposed to ultraviolet light cannot resist the etching of the developer and thus is etched away. In this way, the electron blocking material layer is patterned, and an electron blocking layer is obtained. Due to the hole transport properties of the crosslinking agent, the hole mobility of the electron blocking layer will not decrease significantly, thereby lowering the voltage of the light-emitting device.

For example, the mass of the crosslinking agent is 1-30% of the total mass of the electron blocking layer (for example, 1%, 5%, 10%, 15%, 20%, 25%, or 30%, etc.). Therefore, with an appropriate content of the crosslinking agent, the hole mobility of the electron blocking layer remains relatively high, thereby resulting in a relatively low voltage for the light-emitting device.

In one embodiment, the light-emitting functional layer 120 further comprises a hole injection layer 121, a hole transport layer 122, and an electron blocking layer 123, the hole injection layer 121 being located on the side of the hole transport layer 122 that is close to the first electrode layer 110; and the light-emitting functional layer 120 further comprises a crosslinking layer, which is located between the light-emitting layer 124 and the electron blocking layer 123, or between the electron blocking layer 123 and the hole transport layer 122, or between the hole transport layer 122 and the hole injection layer 121, and the crosslinking layer comprises the crosslinking agent. Thus, the electroactive group in the crosslinking layer is conducive to hole transport, and the presence of the crosslinking layer can improve the hole transport performance of the light-emitting device and lower the voltage of the light-emitting device.

In one embodiment, the light-emitting functional layer 120 further comprise an electron injection layer 125, an electron transport layer 126 and a hole blocking layer 127 that are sequentially stacked, the electron injection layer 125 being located on the side of the electron transport layer 126 that is close to the second electrode layer 130.

In one embodiment, at least one of the electron injection layer 125, the electron transport layer 126, and the hole blocking layer 127 comprises a crosslinking agent, and the crosslinking agent has an electroactive group including at least one of imidazole, pyridine, triazine and pyrimidine. Thus, it is conducive to the transport of electrons in the light-emitting device.

In one embodiment, the electron injection layer 125 comprises a crosslinking agent, and the mass of the crosslinking agent is 1-30% of the total mass of the electron injection layer 125 (for example, 1%, 5%, 10%, 15%, 20%, 25%, or 30%, etc.).

In one embodiment, the electron transport layer 126 comprises a crosslinking agent; and the mass of the crosslinking agent is 1-30% of the total mass of the electron transport layer (for example, 1%, 5%, 10%, 15%, 20%, 25%, or 30%, etc.).

In one embodiment, the hole blocking layer 127 comprises a crosslinking agent; and the mass of the crosslinking agent is 1-30% of the total mass of the hole blocking layer (for example, 1%, 5%, 10%, 15%, 20%, 25%, or 30%, etc.).

In one embodiment, the light-emitting functional layer 120 further includes a crosslinking layer, which is located between the light-emitting layer 124 and the hole blocking layer 127, or between the hole blocking layer 127 and the electron transport layer 126, or between the electron transport layer 126 and the electron injection layer 125, and the crosslinking layer comprises a crosslinking agent.

It can be understood that the electroactive group includes at least one of fluorene, carbazole, aniline, imidazole, pyridine, triazine and pyrimidine. Fluorene, carbazole and aniline are conducive to the transport of holes, and imidazole, pyridine, triazine and pyrimidine are conducive to the transport of electrons. For example, the crosslinking agent in the light-emitting layer 124 may comprise at least one of fluorene, carbazole, aniline, imidazole, pyridine, triazine and pyrimidine; the crosslinking agent in the electron injection layer 125, the electron transport layer 126, and the hole blocking layer 127 comprises at least one of imidazole, pyridine, triazine, and pyrimidine; and the hole injection layer 121, the hole transport layer 122, and the electron blocking layer 123 comprise at least one of fluorene, carbazole, and aniline.

For example, the light-emitting device may be an organic light-emitting diode (OLED), a micro light-emitting diode (Micro LED), a quantum dot light-emitting diode (QLED), etc. The light-emitting device may be light-emitting devices emitting various colors, such as a red light-emitting device R, a green light-emitting device G, and a blue light-emitting device B.

One embodiment of the present application provides a display panel. With reference to the structural schematic diagrams of a display panel shown in FIG. 4 and FIG. 5, the display panel includes: an array substrate 10; a pixel defining layer 20, which is located on a side of the array substrate 10 and comprises a plurality of openings 21; and a plurality of the aforementioned light-emitting devices 30, part of the light-emitting devices 30 being located in the openings 21.

It should be noted that the light-emitting devices are consistent with the foregoing description and will not be elaborated here.

In one embodiment, with reference to FIG. 4, the light-emitting device 30 comprises a first electrode layer 110, a light-emitting functional layer 120, and a second electrode layer 130 that are stacked. The number of layers the light-emitting functional layer 120 being at least one light-emitting layer 124, and the light-emitting functional layer 120 further comprises a hole injection layer 121, a hole transport layer 122, and an electron blocking layer 123, the hole injection layer 121 being located on the side of the hole transport layer 122 that is close to the first electrode layer 110. In the adjacent light-emitting devices 30, the hole injection layers 121 are spaced apart, and/or the hole transport layers 122 are spaced apart. Thus, it is conducive to reducing the residue of the light-emitting layer 124 during the fabrication process.

For example, the light-emitting device may be an organic light-emitting diode (OLED), a micro light-emitting diode (Micro LED), a quantum dot light-emitting diode (QLED), etc. The light-emitting device may be light-emitting devices emitting various colors, such as a red light-emitting device R, a green light-emitting device G, and a blue light-emitting device B.

It can be understood that in the preparation of light-emitting devices of different colors, the film layer materials corresponding to the unwanted light-emitting devices are removed using an etching process, during which the residue of the light-emitting layer materials may occur. Thus, with both the hole injection layers 121 and the hole transport layers 122 arranged in a spaced apart manner, it is beneficial for reducing the residue of the light-emitting layer 124 during the fabrication process.

For example, an encapsulation layer is further provided on the side of the light-emitting device 30 that faces away from the array substrate 10, which may be a thin film encapsulation layer. The encapsulation layer comprises a first inorganic encapsulation layer, an organic encapsulation layer and a second inorganic encapsulation layer that are sequentially stacked. The first inorganic encapsulation layer, the organic encapsulation layer and the second inorganic encapsulation layer use conventional structures and materials that are not the focus of this application, so they will not be elaborated here.

For example, the array substrate 10 may be a base substrate. In some embodiments, the base substrate may be a glass-based substrate. In some embodiments, the base substrate may comprise an organic resin material such as epoxy resins, triazines, silicone resins, or polyimides. For example, the base substrate may be an FR4-type printed circuit board (PCB), or may be a flexible PCB that is easily deformable. In some embodiments, the base substrate may comprise a ceramic material such as silicon nitride, aluminum nitride, or alumina, or comprise a metal or a metal compound. For example, the base substrate may be a metal core PCB (MCPCB) or a metal copper clad laminate (MCCL).

One embodiment of the present application provides a preparation method for a display panel. With reference to the schematic flowchart of a preparation method for a display panel shown in FIG. 6, the preparation method for a display panel includes the following steps.

S100: preparing a first electrode layer on a side of an array substrate.

It should be noted that the array substrate and the first electrode layer are consistent with the foregoing description and will not be elaborated here.

For example, a first electrode material layer as a whole can be prepared on a side of a array substrate, and is patterned to obtain a first electrode layer.

S200: preparing a pixel defining layer on the side of the first electrode layer that faces away from the array substrate, with the pixel defining layer comprising a plurality of openings, and the first electrode layer being at least partially exposed through the openings.

It should be noted that the pixel defining layer is consistent with the foregoing description and will not be elaborated here.

S300: sequentially preparing a light-emitting functional layer and a second electrode layer in the openings.

It should be noted that the light-emitting functional layer and the second electrode layer are consistent with the foregoing description and will not be elaborated here.

For example, the preparation of a pixel defining layer on the side of the first electrode layer that faces away from the array substrate includes: preparing a pixel defining material layer as a whole on the side of the first electrode layer that faces away from the array substrate, the whole pixel defining material layer being an inorganic material; and patterning the pixel defining material layer by means of a dry etching process to obtain the pixel defining layer,
wherein a raw material of the light-emitting functional layer includes the aforementioned crosslinking agent, or a crosslinking agent prepared using the aforementioned preparation method.

It should be noted that the crosslinking agent is consistent with the foregoing description and will not be elaborated here.

In one embodiment, the preparation of the light-emitting functional layer in the openings includes: sequentially preparing a hole injection layer, a hole transport layer, an electron blocking layer, and at least one light-emitting layer in the openings, with the raw materials for at least one of the hole injection layer, the hole transport layer, the electron blocking layer and the light-emitting layer including the crosslinking agent.

In one embodiment, the preparation of the hole injection layers in the openings includes: preparing a hole injection material layer as a whole on the side of the pixel defining layer that faces away from the array substrate, the hole injection material layer comprising the crosslinking agent; and patterning the hole injection material layer by means of a photolithography process to obtain the hole injection layers that are spaced apart.

In one embodiment, after preparing the hole injection layers in the openings, the preparation of the hole transport layers in the openings includes: preparing a hole transport material layer as a whole on the side of the pixel defining layer that faces away from the array substrate, the hole transport material layer comprising the crosslinking agent; and patterning the hole transport material layer by means of a photolithography process to obtain the hole transport layers that are spaced apart.

In one embodiment, after preparing the hole transport layers in the openings, the preparation of the light-emitting layers in the openings includes: preparing a light-emitting material layer as a whole on the side of the pixel defining layer that faces away from the array substrate, the light-emitting material layer comprising the crosslinking agent; and patterning the light-emitting material layer by means of a photolithography process to obtain the light-emitting layers that are spaced apart.

In one embodiment, the preparation of a hole injection layer, a hole transport layer, an electron blocking layer, and a light-emitting layer in sequence in the openings includes the following steps: preparing a hole injection material layer as a whole on the side of the pixel defining layer that faces away from the array substrate; preparing a hole transport material layer as a whole on the side of the hole injection material layer that faces away from the array substrate; preparing an electron blocking material layer as a whole on the side of the hole transport material layer that faces away from the array substrate; preparing a light-emitting material layer as a whole on the side of the electron blocking material layer that faces away from the array substrate; and patterning the hole injection material layer, the hole transport material layer, the electron blocking material layer, and the light-emitting material layer by means of a photolithography process to obtain the hole injection layer, the hole transport layer, the electron blocking layer and the light-emitting layer.

In one embodiment, a plurality of light-emitting devices include a first light-emitting device, a second light-emitting device, and a third light-emitting device, and the preparation of hole injection layers, hole transport layers, electron blocking layers, and light-emitting layers in sequence in the openings includes the following steps:
sequentially preparing a hole injection material layer, a hole transport material layer, an electron blocking material layer, and a light-emitting material layer of the first light-emitting device on the side of the pixel defining layer that faces away from the array substrate; and patterning the hole injection material layer, the hole transport material layer, the electron blocking material layer, and the light-emitting material layer to obtain the hole injection layer, the hole transport layer, the electron blocking layer and the light-emitting layer of the first light-emitting device;
sequentially preparing a hole injection material layer, a hole transport material layer, an electron blocking material layer, and a light-emitting material layer of the second light-emitting device on the side of the pixel defining layer that faces away from the array substrate; and patterning the hole injection material layer, the hole transport material layer, the electron blocking material layer, and the light-emitting material layer to obtain the hole injection layer, the hole transport layer, the electron blocking layer and the light-emitting layer of the second light-emitting device; and
sequentially preparing a hole injection material layer, a hole transport material layer, an electron blocking material layer, and a light-emitting material layer of the third light-emitting device on the side of the pixel defining layer that faces away from the array substrate; and patterning the hole injection material layer, the hole transport material layer, the electron blocking material layer, and the light-emitting material layer to obtain the hole injection layer, the hole transport layer, the electron blocking layer and the light-emitting layer of the third light-emitting device.

It can be understood that the first light-emitting device, the second light-emitting device and the third light-emitting device may each independently be a red light-emitting device R, a green light-emitting device G and a blue light-emitting device B; and the order of the preparation of the three light-emitting devices, namely the red light-emitting device R, the green light-emitting device G and the blue light-emitting device B, is not limited and can be flexibly selected according to actual conditions, provided that the requirements are met.

The present application will be further described below with reference to specific examples. It should be noted that the following examples are merely used to explain the present application and are not to be construed as limiting the present application.

### Example 1

A red light-emitting device in this example was prepared using a method as follows:

An indium tin oxide (ITO) substrate (anode) was subjected to ultraviolet ozone treatment for 5 min, and spin-coated with poly(3,4-ethylenedioxythiophene):polystyrene sulfonate (PEDOT:PSS) to form a film, followed by annealing at 120° C. for 30 min to obtain a hole injection layer with a thickness of 40 nm; then, a mixed hole transport material solution of compound (2-31) (10 wt %): poly [(N,N′-(4-n-butylphenyl)-N,N′-diphenyl-1,4-phenylenediamine)-ALT-(9,9-di-n-octylfluorenyl-2,7-diyl)] (TFB) was spin-coated to form a film, and the coated substrate was exposed to a 365 nm light source; subsequently, the coated substrate was soaked in toluene for 10 s, then dried by means of rotary evaporation, and then spin-coated with a red quantum dot solution to form a film, followed by annealing at 100° C. for 30 min to obtain a red quantum dot light-emitting layer with a thickness of 20 nm; then a zinc oxide (ZnO) solution was spin-coated to form a film, followed by annealing at 80° C. for 30 min to obtain an electron transport layer with a thickness of 50 nm; and finally a 100 nm aluminum (Al) electrode was evaporated as a cathode.

Examples 2-14: the method for preparing a light-emitting device was basically the same as that in Example 1, except that the type of the crosslinking agent in the hole transport layer was different, as detailed in Table 1 below.

Examples 15-20: the method for preparing a light-emitting device was basically the same as that in Example 1, except that the content of the crosslinking agent in the hole transport layer was different, as detailed in Table 1 below.

Comparative Example 1: the method for preparing a light-emitting device was basically the same as that in Example 1, except that the crosslinking agent in the hole transport layer was replaced with D1, as detailed in Table 1 below. The molecular formula of D1 was

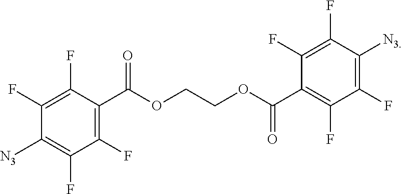 [SMILES: [N-]=[N+]=Nc1c(F)c(F)c(C(=O)OCCOC(=O)c2c(F)c(F)c(N=[N+]=[N-])c(F)c2F)c(F)c1F]

The voltage, external quantum efficiency (EQE) and lifetime of the light-emitting devices of Examples 1-20 and Comparative Example 1 are shown in Table 1 below.

TABLE 1

| | Type of | Content of | | | |
|---|---|---|---|---|---|
| | crosslinking | crosslinking | | | |
| | agent in | agent in | | | |
| | hole | hole | Voltage | | |
| | transport | transport | (@J10)/ | EQE/ | Lifetime |
| Example | layer | layer | V | % | T95/h |
| Example 1 | 2-32 | 10% | 5.41 | 6.4 | 4223 |
| Example 2 | 2-33 | 10% | 5.81 | 7.0 | 3305 |
| Example 3 | 2-34 | 10% | 6.20 | 5.2 | 3673 |
| Example 4 | 2-35 | 10% | 6.05 | 5.0 | 3821 |
| Example 5 | 2-36 | 10% | 5.90 | 5.7 | 4019 |
| Example 6 | 2-3 | 10% | 5.67 | 5.3 | 3780 |
| Example 7 | 2-5 | 10% | 5.72 | 6.1 | 3777 |
| Example 8 | 2-8 | 10% | 5.97 | 7.0 | 3209 |
| Example 9 | 2-15 | 10% | 5.87 | 5.7 | 3375 |
| Example 10 | 2-18 | 10% | 6.59 | 5.3 | 4792 |
| Example 11 | 2-20 | 10% | 5.73 | 5.8 | 4021 |
| Example 12 | 2-22 | 10% | 5.65 | 6.4 | 3782 |
| Example 13 | 2-28 | 10% | 5.88 | 5.6 | 3678 |
| Example 14 | 2-31 | 10% | 6.12 | 7.8 | 3112 |
| Example 15 | 2-32 | 1% | 5.76 | 5.7 | 3654 |
| Example 16 | 2-32 | 5% | 5.44 | 5.9 | 3987 |
| Example 17 | 2-32 | 15% | 5.87 | 6.5 | 4321 |
| Example 18 | 2-32 | 30% | 6.26 | 4.9 | 3321 |
| Example 19 | 2-32 | 35% | 6.75 | 4.7 | 3078 |
| Example 20 | 2-32 | 0.5% | 4.91 | 2.3 | 2310 |
| Comparative | D1 | 10% | 7.45 | 4.7 | 3010 |
| Example 1 | | | | | |

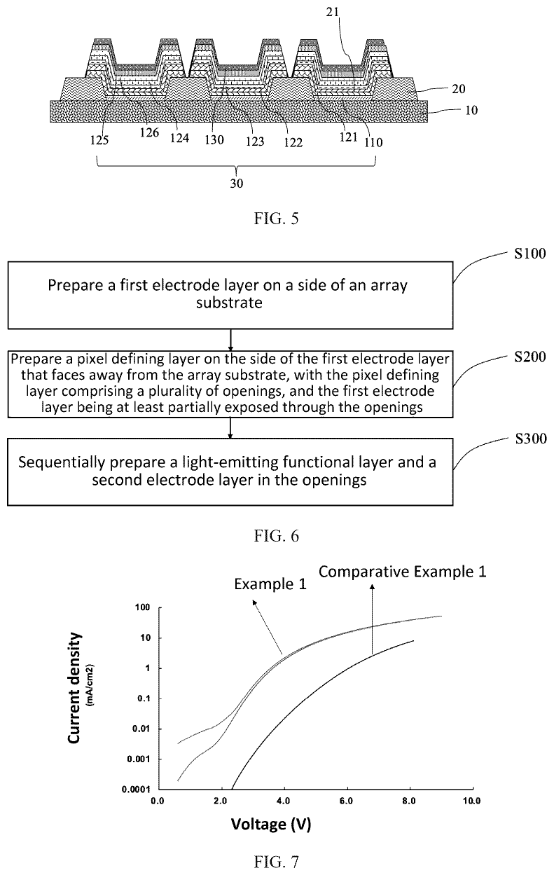

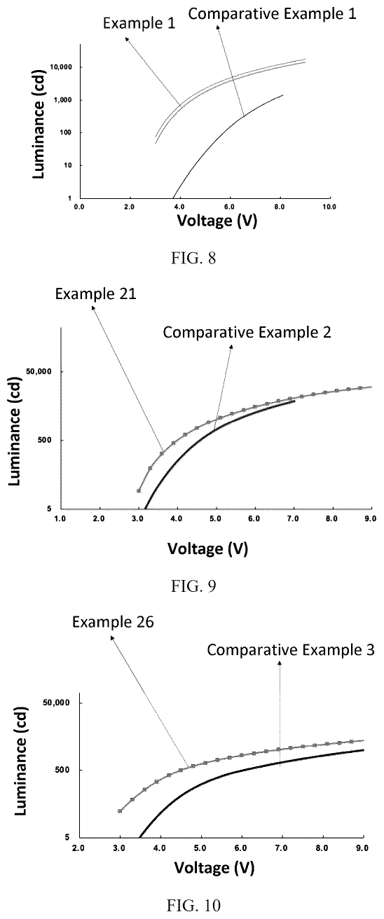

The voltage-current density curves of the light-emitting devices in Example 1 and Comparative Example 1 are shown in FIG. 7, and the voltage-luminance curves are shown in FIG. 8. As can be seen in combination with the data in Table 1, the light-emitting devices using the crosslinking agent of the present application had better performance.

### Examples 21-25 and Comparative Example 2

The method for preparing a light-emitting device was basically the same as that in Example 1, except that the light-emitting layer material was a green light-emitting layer material, and the type of the crosslinking agents in the hole transport layer was different, as detailed in Table 2 below.

TABLE 2

| | Type of | Content of | | | |
|---|---|---|---|---|---|
| | crosslinking | crosslinking | | | |
| | agent in | agent in | | | |
| | hole | hole | Voltage | | |
| | transport | transport | (@J10)/ | EQE/ | Lifetime |
| Example | layer | layer | V | % | T95/h |
| Example 21 | 2-32 | 10% | 4.87 | 8.9 | 1223 |
| Example 22 | 2-33 | 10% | 4.74 | 12.0 | 1305 |
| Example 23 | 2-34 | 10% | 4.21 | 13.7 | 2274 |
| Example 24 | 2-35 | 10% | 4.81 | 10.1 | 2121 |
| Example 25 | 2-36 | 10% | 4.55 | 9.9 | 1019 |
| Comparative | D1 | 10% | 4.97 | 8.8 | 1010 |
| Example 2 | | | | | |

The voltage-luminance curves of the light-emitting devices in Example 21 and Comparative Example 2 are shown in FIG. 9. As can be seen in combination with the data in Table 2, the light-emitting devices using the crosslinking agent of the present application had better performance.

### Examples 26-30 and Comparative Example 3

The method for preparing a light-emitting device was basically the same as that in Example 1, except that the light-emitting layer material was a blue light-emitting layer material, and the type of the crosslinking agents in the hole transport layer was different, as detailed in Table 3 below.

TABLE 3

| | Type of | Content of | | | |
|---|---|---|---|---|---|
| | crosslinking | crosslinking | | | |
| | agent in | agent in | | | |
| | hole | hole | Voltage | | |
| | transport | transport | (@J10)/ | EQE/ | Lifetime |
| Example | layer | layer | V | % | T95/h |
| Example 26 | 2-32 | 10% | 6.23 | 7.0 | 11 |
| Example 27 | 2-33 | 10% | 6.31 | 7.1 | 15 |
| Example 28 | 2-34 | 10% | 5.90 | 6.5 | 18 |
| Example 29 | 2-35 | 10% | 6.00 | 8.8 | 22 |
| Example 30 | 2-36 | 10% | 5.71 | 9.9 | 34 |
| Comparative | D1 | 10% | 7.30 | 6.0 | 10 |
| Example 3 | | | | | |

The voltage-luminance curves of the light-emitting devices in Example 26 and Comparative Example 3 are shown in FIG. 10. As can be seen in combination with the data in Table 3, the light-emitting devices using the crosslinking agent of the present application had better performance.

Example 31 A red light-emitting device in this example was prepared using a method as follows:

An indium tin oxide (ITO) substrate (anode) was subjected to ultraviolet ozone treatment for 5 min, and spin-coated with poly(3,4-ethylenedioxythiophene):polystyrene sulfonate (PEDOT:PSS) to form a film, followed by annealing at 120° C. for 30 min to obtain a hole injection layer with a thickness of 40 nm; then, TFB as a hole transport material solution was spin-coated to form a film, and a solution of compound (2-32) (4 wt %): red quantum dots was then spin-coated to form a film, and the coated substrate was then exposed to a 365 nm light source and developed using an n-octane solution to obtain a red quantum dot light-emitting layer with a thickness of 20 nm; then a zinc oxide (ZnO) solution was spin-coated to form a film, followed by annealing at 80° C. for 30 min to obtain an electron transport layer with a thickness of 50 nm; and finally a 100 nm aluminum (Al) electrode was evaporated as a cathode.

Examples 32-44: the method for preparing a light-emitting device was basically the same as that in Example 31, except that the type of the crosslinking agents in the light-emitting layer was different, as detailed in Table 4 below.

Examples 45-50: the method for preparing a light-emitting device was basically the same as that in Example 31 except that the content of the crosslinking agents in the light-emitting layer was different, as detailed in Table 4 below.

Comparative Example 4: the method for preparing a light-emitting device was basically the same as that in Example 31, except that the crosslinking agent in the light-emitting layer was replaced with D1, as detailed in Table 4 below. The molecular formula of D1 was

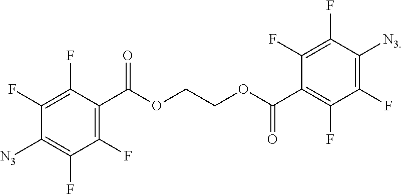 [SMILES: [N-]=[N+]=Nc1c(F)c(F)c(C(=O)OCCOC(=O)c2c(F)c(F)c(N=[N+]=[N-])c(F)c2F)c(F)c1F]

The voltage, external quantum efficiency (EQE) and lifetime of the light-emitting devices of Examples 31-50 and Comparative Example 4 are shown in Table 4 below.

TABLE 4

| | Type of | Content of | | | |
|---|---|---|---|---|---|
| | crosslinking | crosslinking | | | |
| | agent in | agent in | | | |
| | light- | light- | Voltage | | |
| | emitting | emitting | (@J10)/ | EQE/ | Lifetime |
| Example | layer | layer | V | % | T95/h |
| Example 31 | 2-32 | 4% | 5.30 | 13.6 | 5124 |
| Example 32 | 2-33 | 4% | 6.12 | 9.0 | 3275 |
| Example 33 | 2-34 | 4% | 6.23 | 10.1 | 3851 |
| Example 34 | 2-35 | 4% | 6.05 | 8.0 | 2821 |
| Example 35 | 2-36 | 4% | 5.67 | 9.7 | 4031 |
| Example 36 | 2-3 | 4% | 6.23 | 9.0 | 3211 |
| Example 37 | 2-5 | 4% | 6.22 | 9.2 | 3601 |
| Example 38 | 2-8 | 4% | 6.71 | 9.5 | 3729 |
| Example 39 | 2-15 | 4% | 6.31 | 9.8 | 4012 |
| Example 40 | 2-18 | 4% | 5.73 | 8.9 | 3802 |
| Example 41 | 2-20 | 4% | 5.89 | 9.4 | 3623 |
| Example 42 | 2-22 | 4% | 6.81 | 10.2 | 2890 |
| Example 43 | 2-28 | 4% | 5.72 | 9.8 | 4078 |
| Example 44 | 2-31 | 4% | 5.83 | 9.4 | 4555 |
| Example 45 | 2-32 | 1% | 5.55 | 8.7 | 5111 |
| Example 46 | 2-32 | 5% | 5.72 | 9.7 | 4430 |
| Example 47 | 2-32 | 15% | 5.54 | 8.9 | 3890 |
| Example 48 | 2-32 | 30% | 4.98 | 6.2 | 2610 |
| Example 49 | 2-32 | 35% | 4.52 | 5.1 | 2390 |
| Example 50 | 2-32 | 0.5% | 5.66 | 8.6 | 2990 |
| Comparative | D1 | 4% | 7.67 | 8.5 | 2510 |
| Example 4 | | | | | |

### Examples 51-55 and Comparative Example 5

The method for preparing a light-emitting device was basically the same as that in Example 31, except that the light-emitting layer material was a green light-emitting layer material, and the type of the crosslinking agents in the light-emitting layer was different, as detailed in Table 5 below.

TABLE 5

| | Type of | Content of | | | |
|---|---|---|---|---|---|
| | crosslinking | crosslinking | | | |
| | agent in | agent in | | | |
| | light- | light- | Voltage | | |
| | emitting | emitting | (@J10)/ | EQE/ | Lifetime |
| Example | layer | layer | V | % | T95/h |
| Example 51 | 2-32 | 10% | 6.12 | 4.6 | 820 |
| Example 52 | 2-33 | 10% | 4.50 | 6.2 | 2012 |
| Example 53 | 2-34 | 10% | 5.48 | 4.9 | 568 |
| Example 54 | 2-35 | 10% | 6.12 | 5.5 | 1280 |
| Example 55 | 2-36 | 10% | 6.01 | 4.7 | 1482 |
| Comparative | D1 | 10% | 7.80 | 4.0 | 190 |
| Example 5 | | | | | |

### Examples 56-60 and Comparative Example 6

The method for preparing a light-emitting device was basically the same as that in Example 31, except that the light-emitting layer material was a blue light-emitting layer material, and the type of the crosslinking agents in the light-emitting layer was different, as detailed in Table 6 below.

TABLE 6

| | Type of | Content of | | | |
|---|---|---|---|---|---|
| | crosslinking | crosslinking | | | |
| | agent in | agent in | | | |
| | light- | light- | Voltage | | |
| | emitting | emitting | (@J10)/ | EQE/ | Lifetime |
| Example | layer | layer | V | % | T95/h |
| Example 56 | 2-32 | 10% | 6.82 | 3.8 | 9 |
| Example 57 | 2-33 | 10% | 6.21 | 4.2 | 14 |
| Example 58 | 2-34 | 10% | 7.11 | 3.3 | 8 |
| Example 59 | 2-35 | 10% | 6.92 | 5.1 | 21 |
| Example 60 | 2-36 | 10% | 5.82 | 6.8 | 31 |
| Comparative | D1 | 10% | 8.81 | 3.2 | 8 |
| Example 6 | | | | | |

The basic principle of the present application is described above with reference to specific embodiments. However, it should be noted that the advantages, benefits, effects, and the like mentioned in the present application are merely exemplary rather than limiting, and these advantages, benefits, effects, and the like cannot be considered to be necessary for each embodiment of the present application. In addition, the specific details disclosed above are for the purpose of illustration and ease of understanding only, and not limitations, and the details above shall not be construed as limiting the present application to implementations that necessarily use the specific details above.

The foregoing description has been provided for the purposes of illustration and description. Moreover, these descriptions are not intended to limit the embodiments of the present application to the form disclosed herein.

1. A crosslinking agent, comprising:
an electroactive group and a crosslinking group, wherein the electroactive group and the crosslinking group are bonded, and the crosslinking group is located on at least a portion of the periphery of the electroactive group.

2. The crosslinking agent according to claim 1, wherein the electroactive group comprises at least one of fluorene, carbazole, aniline, imidazole, pyridine, triazine and pyrimidine.

3. The crosslinking agent according to claim 1, wherein the electroactive group comprises at least one of 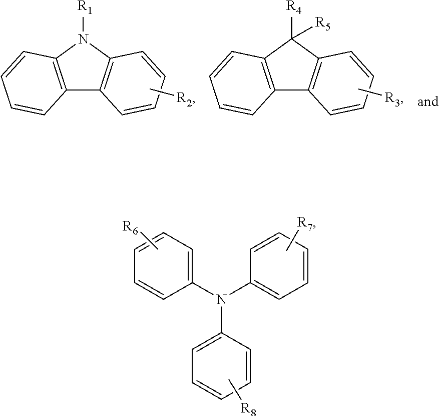
wherein R₁, R₂, R₃, R₄, R₅, R₆, R₇ and R₈ each independently comprise at least one of H, F, Cl, Br, I, CN, NO₂, a liner alkyl group having 1-40 carbon atoms, a branched alkyl group having 2-40 carbon atoms, a cyclic alkyl group having 3-40 carbon atoms, and a cyclic amine group having 2-40 carbon atoms.

4. The crosslinking agent according to claim 3, wherein at least one H atom of the linear alkyl group having 1-40 carbon atoms is substituted with F, Cl, Br, I, CN or NO₂; or at least one H atom of the branched alkyl group having 3-40 carbon atoms is substituted with F, Cl, Br, I, CN, or NO₂; or at least one H atom of the cyclic alkyl group having 3-40 carbon atoms is substituted with F, Cl, Br, I, CN, or NO₂; or at least one H atom of the branched alkyl group having 2-40 carbon atoms is substituted with F, Cl, Br, I, CN, or NO₂; or at least one H atom of the cyclic amine group having 2-40 carbon atoms is substituted with F, Cl, Br, I, CN, or NO₂; or at least two non-adjacent CH₂ groups of the linear alkyl group having 1-40 carbon atoms are replaced with O or S; or at least two non-adjacent CH₂ groups of the branched alkyl group having 3-40 carbon atoms are replaced with O or S; or at least two non-adjacent CH₂ groups of the cyclic alkyl group having 3-40 carbon atoms are replaced with O or S; or at least two non-adjacent CH₂ groups of the branched alkyl group having 2-40 carbon atoms are replaced with O or S; or at least two non-adjacent CH₂ groups of the cyclic amine group having 2-40 carbon atoms are replaced with O or S.

5. The crosslinking agent according to claim 1, wherein the crosslinking group comprises a photocrosslinking group.

6. The crosslinking agent according to claim 5, wherein the crosslinking group comprises at least one of 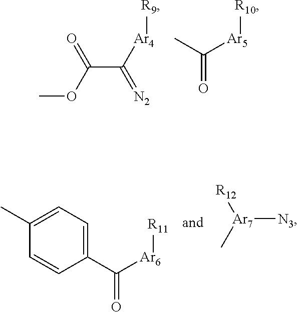
wherein Ar₄, Ar₅, Ar₆, and Ar₇ each independently comprise an aromatic or heteroaromatic ring; and
R₉, R₁₀, R₁₁ and R₁₂ each independently comprise at least one of H, F, Cl, Br, I, CN, NO₂, a liner alkyl group having 1-40 carbon atoms, a branched alkyl group having 3-40 carbon atoms, a cyclic alkyl group having 3-40 carbon atoms, a branched alkyl group having 2-40 carbon atoms, and a cyclic amine group having 2-40 carbon atoms, wherein at least one H atom of the linear alkyl group having 1-40 carbon atoms is substituted with F, Cl, Br, I, CN or NO₂; or at least one H atom of the branched alkyl group having 3-40 carbon atoms is substituted with F, Cl, Br, I, CN, or NO₂; or at least one H atom of the cyclic alkyl group having 3-40 carbon atoms is substituted with F, Cl, Br, I, CN, or NO₂; or at least one H atom of the branched alkyl group having 2-40 carbon atoms is substituted with F, Cl, Br, I, CN, or NO₂; or at least one H atom of the cyclic amine group having 2-40 carbon atoms is substituted with F, Cl, Br, I, CN, or NO₂; or at least two non-adjacent CH₂ groups of the linear alkyl group having 1-40 carbon atoms are replaced with O or S; or at least two non-adjacent CH₂ groups of the branched alkyl group having 3-40 carbon atoms are replaced with O or S; or at least two non-adjacent CH₂ groups of the cyclic alkyl group having 3-40 carbon atoms are replaced with O or S; or at least two non-adjacent CH₂ groups of the branched alkyl group having 2-40 carbon atoms are replaced with O or S; or at least two non-adjacent CH₂ groups of the cyclic amine group having 2-40 carbon atoms are replaced with O or S.

7. The crosslinking agent according to claim 1, wherein the crosslinking agent comprises a structure represented by formula (1): 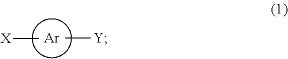
wherein the electroactive group comprises Ar, and the crosslinking group comprises X and Y;
Ar comprises a structure represented by at least one of formulae (1-1) to (1-3): 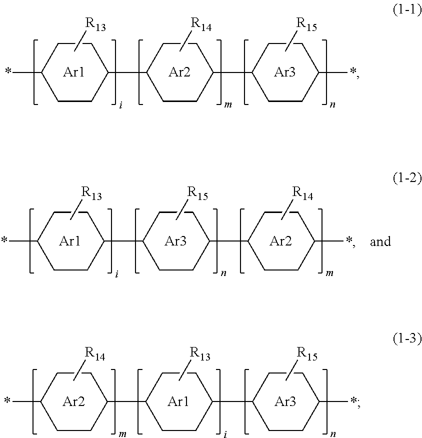
in formulae (1-1) to (1-3), * represents a bonding site for X and Y;
X is bonded to at least one site of the site represented by * and a site on Ar1 to Ar3 and R₁₃ to R₁₅, and Y is bonded to at least one site of the site represented by * and a site on Ar1 to Ar3 and R₁₃ to R₁₅;
wherein Ar1, Ar2, and Ar3 each independently comprise at least one of 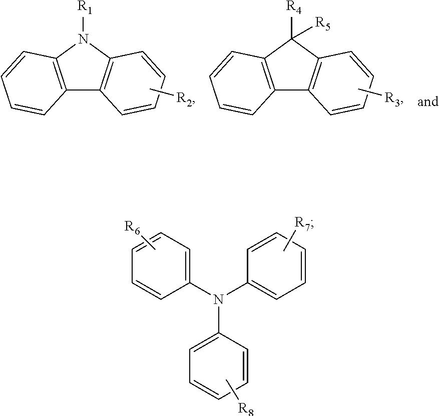
X and Y each independently comprise at least one of 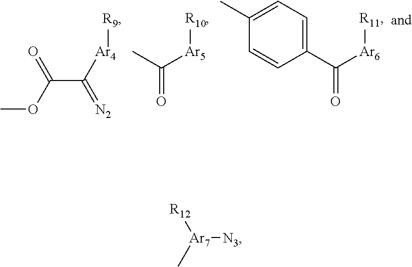
wherein R₁, R₂, R₃, R₄, R₅, R₆, R₇, R₈, R₉, R₁₀, R₁₁, R₁₂, R₁₃, R₁₄ and R₁₅ each independently comprise at least one of H, F, Cl, Br, I, CN, NO₂, a liner alkyl group having 1-40 carbon atoms, a branched alkyl group having 3-40 carbon atoms, a cyclic alkyl group having 3-40 carbon atoms, a branched alkyl group having 2-40 carbon atoms, and a cyclic amine group having 2-40 carbon atoms; and
Ar₄, Ar₅, Ar₆, and Ar₇ each independently comprise an aromatic or heteroaromatic ring;
the number of R₁₃, R₁₄ and R₁₅ is each independently at least one; and
i+m+n≤18, and i, m and n are not all 0.

8. The crosslinking agent according to claim 7, wherein the sum of the number of X and the number of Y in the same crosslinking agent molecular structure is greater than or equal to 2 and less than or equal to 20;
at least one H atom of the linear alkyl group having 1-40 carbon atoms is substituted with F, Cl, Br, I, CN or NO₂; or at least one H atom of the branched alkyl group having 3-40 carbon atoms is substituted with F, Cl, Br, I, CN, or NO₂; or at least one H atom of the cyclic alkyl group having 3-40 carbon atoms is substituted with F, Cl, Br, I, CN, or NO₂; or at least one H atom of the branched alkyl group having 2-40 carbon atoms is substituted with F, Cl, Br, I, CN, or NO₂; or at least one H atom of the cyclic amine group having 2-40 carbon atoms is substituted with F, Cl, Br, I, CN, or NO₂; or at least two non-adjacent CH₂ groups of the linear alkyl group having 1-40 carbon atoms are replaced with O or S; or at least two non-adjacent CH₂ groups of the branched alkyl group having 3-40 carbon atoms are replaced with O or S; or at least two non-adjacent CH₂ groups of the cyclic alkyl group having 3-40 carbon atoms are replaced with O or S; or at least two non-adjacent CH₂ groups of the branched alkyl group having 2-40 carbon atoms are replaced with O or S; or at least two non-adjacent CH₂ groups of the cyclic amine group having 2-40 carbon atoms are replaced with O or S.

9. The crosslinking agent according to claim 8, wherein the crosslinking agent comprises a structure represented by at least one of formulae (2-1) to (2-36):

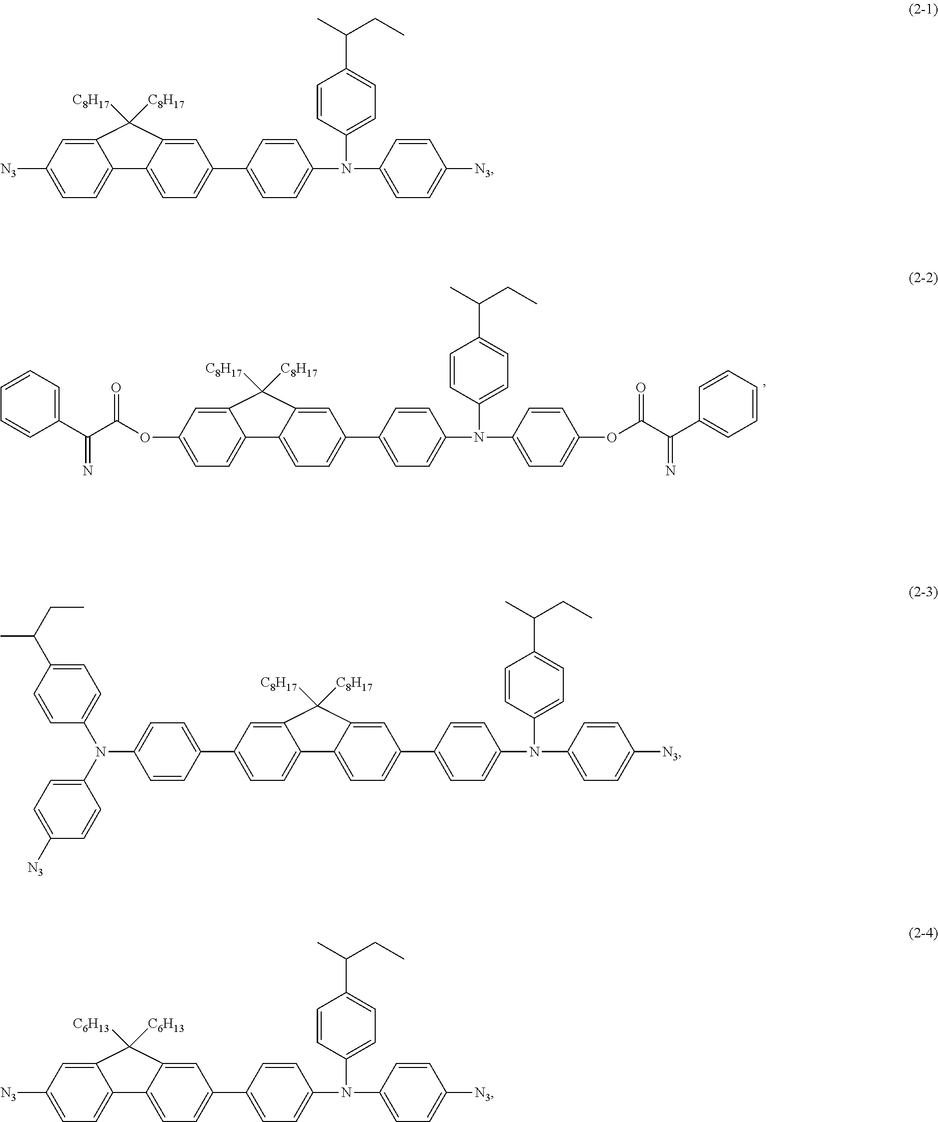

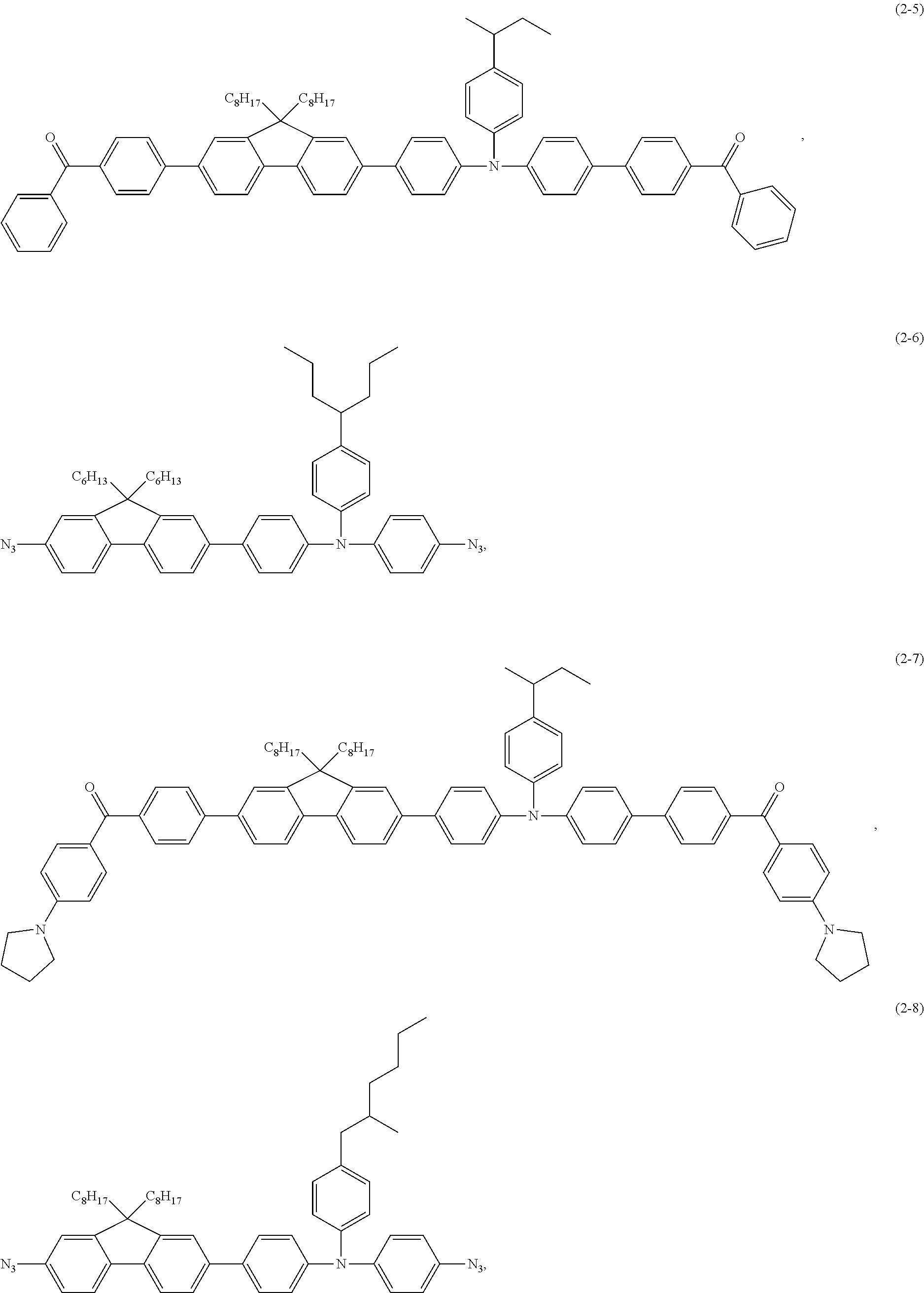

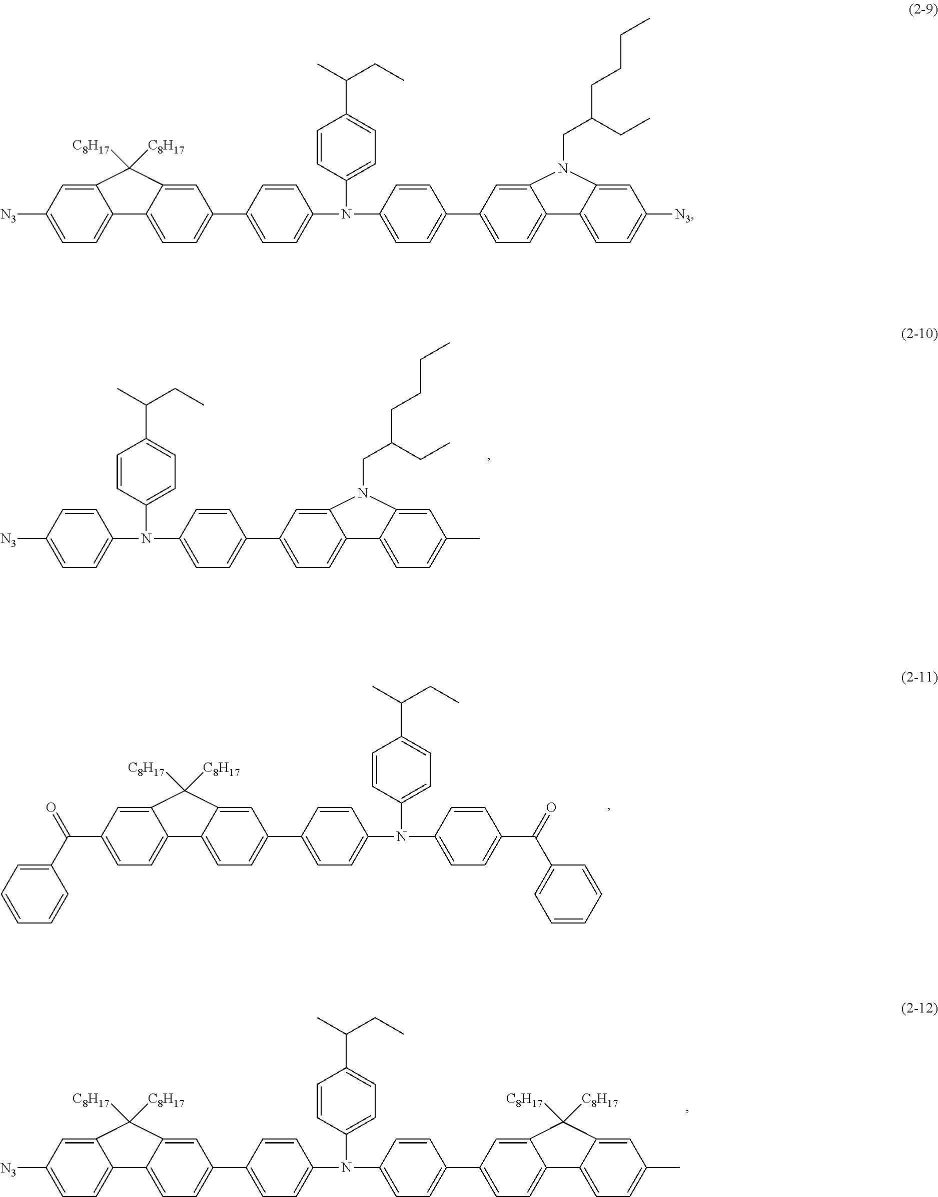

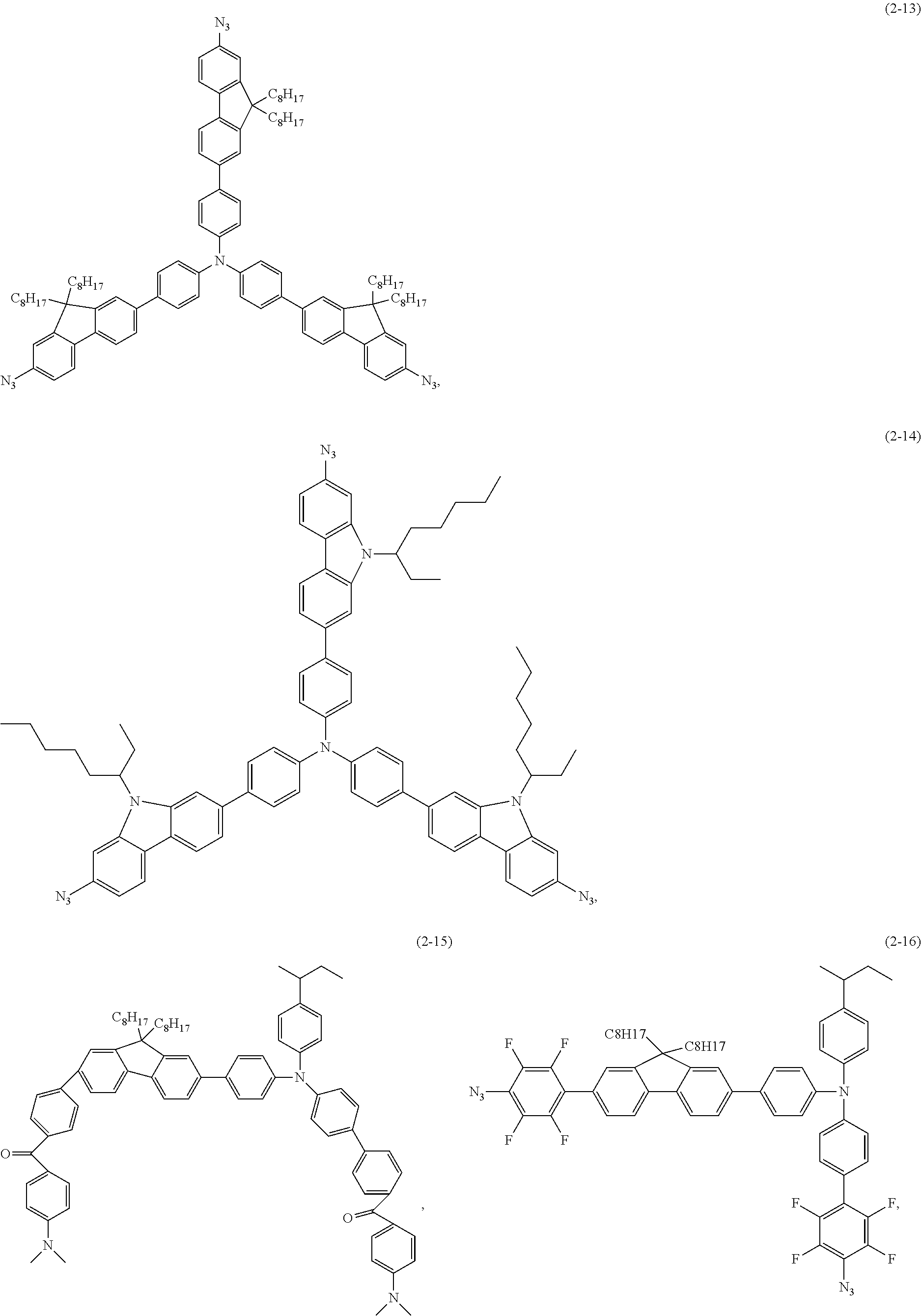

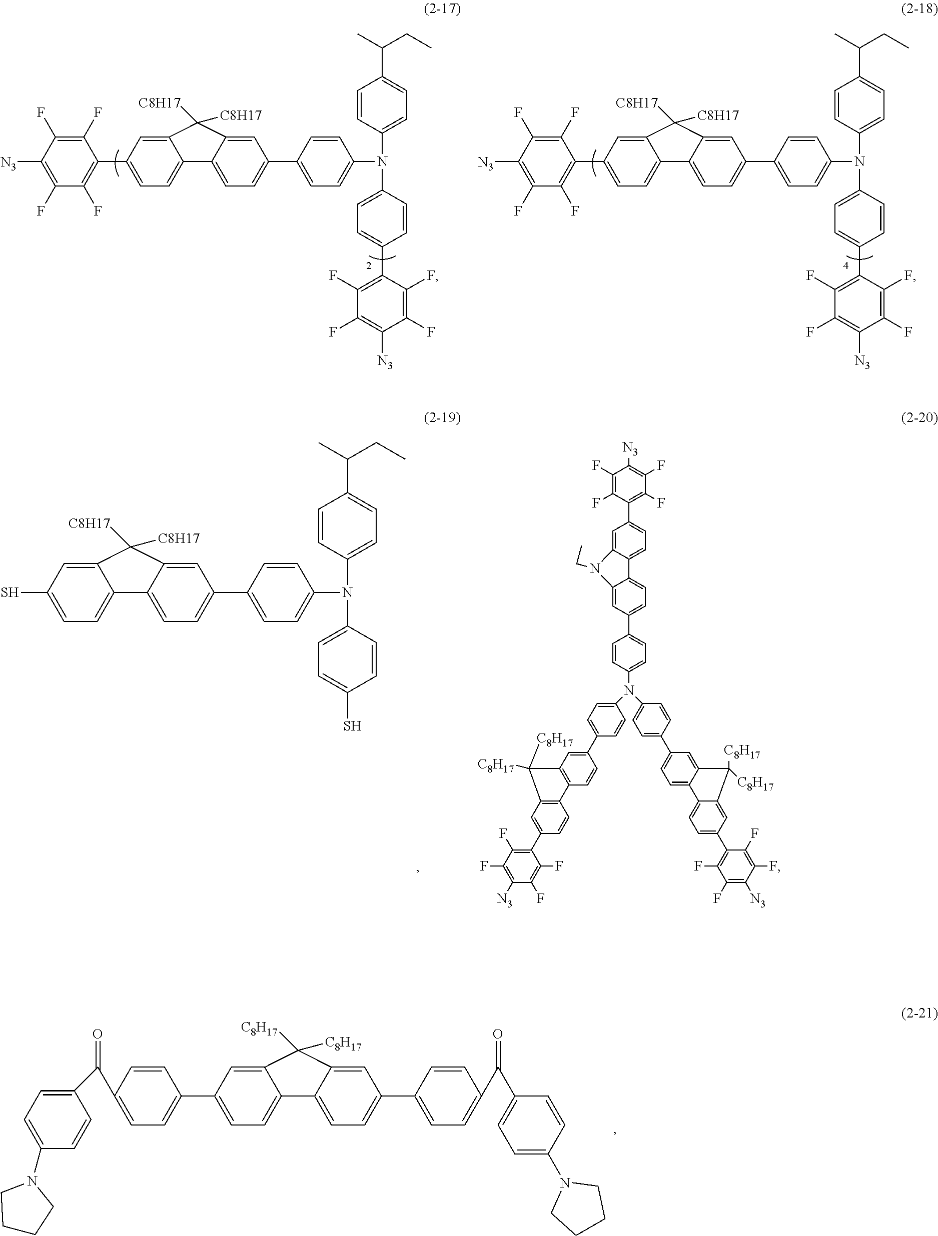

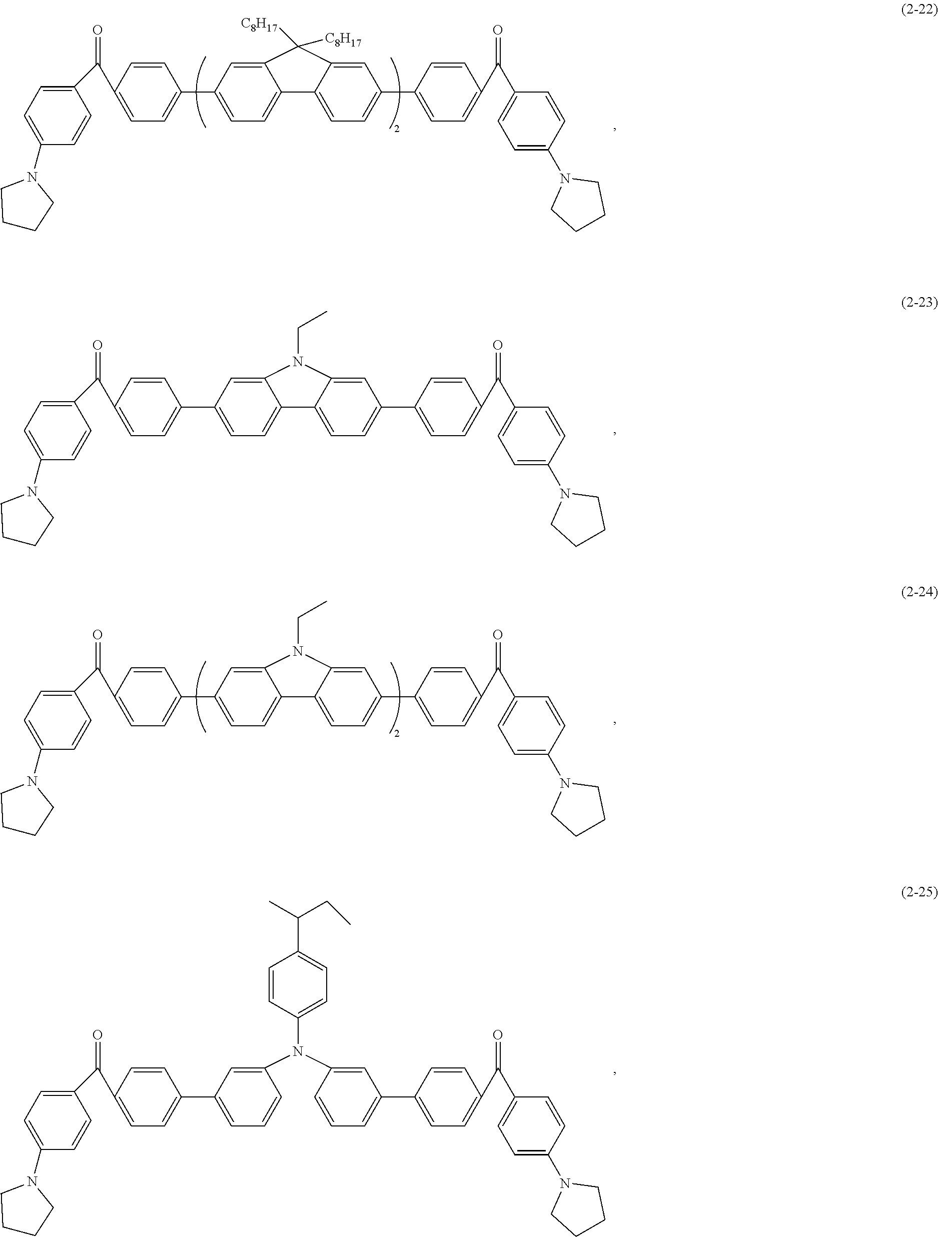

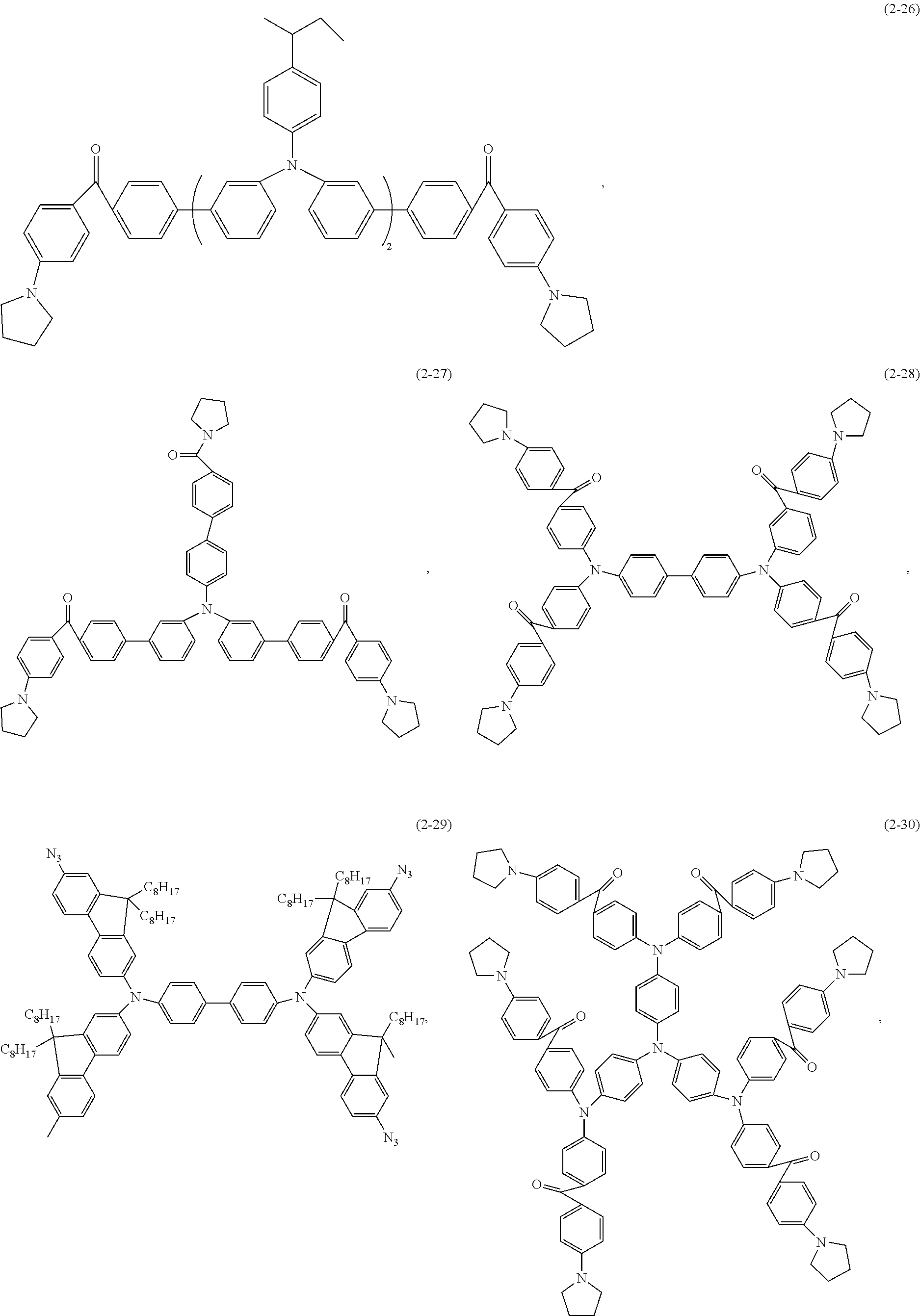

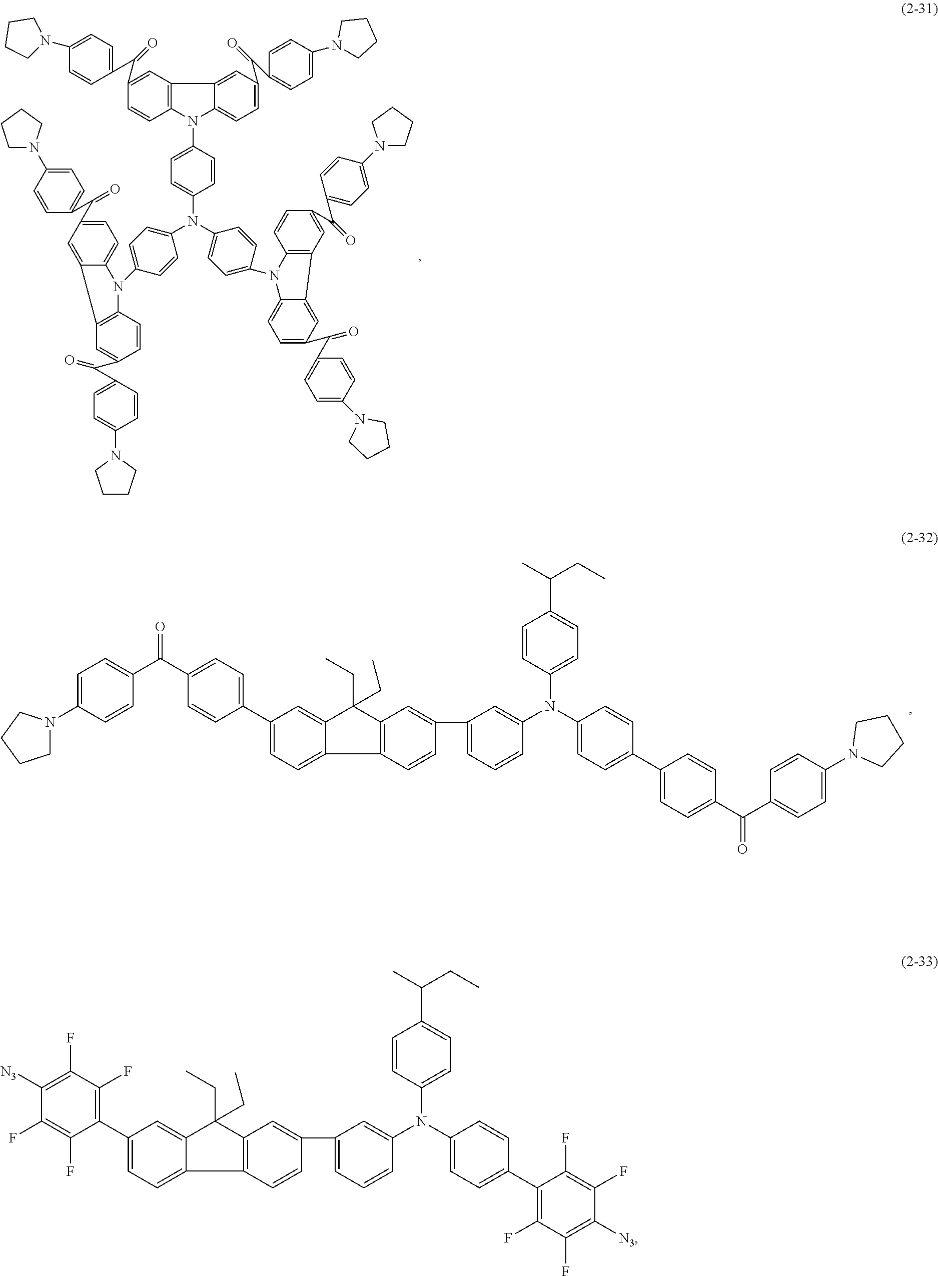

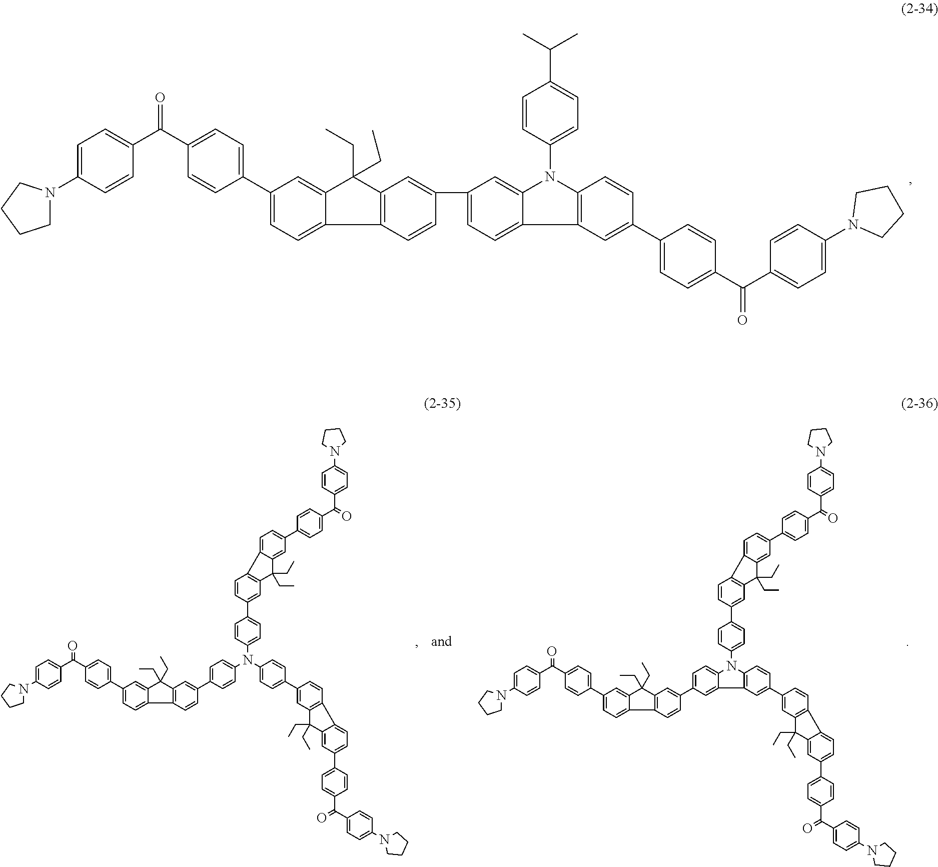

10. A light-emitting device, comprising:
a first electrode layer, a light-emitting functional layer and a second electrode layer that are stacked, wherein
a raw material of the light-emitting functional layer comprises the crosslinking agent of claim 1.

11. The light-emitting device according to claim 10, wherein the light-emitting functional layer comprises at least one light-emitting layer, and the light-emitting layer comprises the crosslinking agent;
the mass of the crosslinking agent is 1-30% of the total mass of the light-emitting layer; and
the light-emitting layer comprises a quantum dot light-emitting layer.

12. The light-emitting device according to claim 11, wherein the light-emitting functional layer further comprises at least one of a hole injection layer, a hole transport layer, and an electron blocking layer that are located between the first electrode layer and the light-emitting layer; and
at least one of the hole injection layer, the hole transport layer, and the electron blocking layer comprises the crosslinking agent, and the crosslinking agent has an electroactive group comprising at least one of fluorene, carbazole, and aniline.

13. The light-emitting device according to claim 12, wherein the hole injection layer comprises the crosslinking agent, the mass of the crosslinking agent being 1-30% of the total mass of the hole injection layer; or the hole transport layer comprises the crosslinking agent, the mass of the crosslinking agent being 1-30% of the total mass of the hole transport layer; or the electron blocking layer comprises the crosslinking agent, the mass of the crosslinking agent being 1-30% of the total mass of the electron blocking layer.

14. The light-emitting device according to claim 11, wherein the light-emitting functional layer further comprises the hole injection layer, the hole transport layer, and the electron blocking layer that are sequentially stacked, the hole injection layer being located on the side of the hole transport layer that is close to the first electrode layer; and
the light-emitting functional layer further comprises a crosslinking layer, which is located between the light-emitting layer and the electron blocking layer, or between the electron blocking layer and the hole transport layer, or between the hole transport layer and the hole injection layer, and the crosslinking layer comprises the crosslinking agent.

15. The light-emitting device according to claim 11, wherein the light-emitting functional layer further comprises at least one of an electron injection layer, an electron transport layer, and a hole blocking layer that are located between the second electrode layer and the light-emitting layer; and
at least one of the electron injection layer, the electron transport layer, and the hole blocking layer comprises the crosslinking agent, and the crosslinking agent has an electroactive group comprising at least one of imidazole, pyridine, triazine and pyrimidine.

16. The light-emitting device according to claim 15, wherein the electron injection layer comprises the crosslinking agent, the mass of the crosslinking agent being 1-30% of the total mass of the electron injection layer; or the electron transport layer comprises the crosslinking agent, the mass of the crosslinking agent being 1-30% of the total mass of the electron transport layer; or the hole blocking layer comprises the crosslinking agent, the mass of the crosslinking agent being 1-30% of the total mass of the hole blocking layer.

17. The light-emitting device according to claim 11, wherein the light-emitting functional layer further comprises the electron injection layer, the electron transport layer, and the hole blocking layer that are sequentially stacked, the electron injection layer being located on the side of the electron transport layer that is close to the second electrode layer.

18. The light-emitting device according to claim 17, wherein the light-emitting functional layer further comprises a crosslinking layer, which is located between the light-emitting layer and the hole blocking layer, or between the hole blocking layer and the electron transport layer, or between the electron transport layer and the electron injection layer, and the crosslinking layer comprises the crosslinking agent.

19. A display panel, comprising:
an array substrate;
a pixel defining layer, which is located on a side of the array substrate and comprises a plurality of openings; and
a plurality of the light-emitting devices of claim 10, part of the light-emitting devices being located in the openings.

20. The display panel according to claim 19, wherein the light-emitting functional layer comprises a hole injection layer, a hole transport layer, an electron blocking layer, and at least one light-emitting layer that are sequentially stacked, the hole injection layer being located on the side of the hole transport layer that is close to the first electrode layer; and in the adjacent light-emitting devices, the hole injection layers are spaced apart, or the hole transport layers are spaced apart.
